(19) United States
(12) Patent Application Publication
(10) Pub. No.: US 2026/0370104 A1
(43) Pub. Date: Nov. 19, 2026

(54) SYSTEM AND METHOD FOR CONTROLLING A SHAPING MACHINE FOR MAKING HAIRPIN CONDUCTOR ELEMENTS OF AN INDUCTIVE WINDING OF A STATOR

(71) Applicant: I.M.A. INDUSTRIA MACCHINE AUTOMATICHE S.P.A., OZZANO DELL'EMILIA (IT)

(72) Inventors: Marco SPEZIALI, Ozzano Dell'emilia (IT); Davide BARACCANI, Ozzano Dell'emilia (IT); Emanuele SABATANI, Ozzano Dell'emilia (IT)

(21) Appl. No.: 19/477,591

(22) PCT Filed: May 3, 2024
(86) PCT No.: PCT/IB2024/054300

§ 371 Date: Oct. 22, 2025

(30) Foreign Application Priority Data
May 3, 2023 (IT) 102023000008631

(51) Int. Cl. H02K 15/0421

(52) U.S. Cl. CPC H02K 15/0421; H02K 2215/00

(57) ABSTRACT

A system for controlling a shaping machine for making hairpin conductor elements, the system comprising a geometric information source of at least one hairpin conductor element obtained with the shaping machine and a processing device connected to the geometric information source and connectable to the shaping machine;
wherein the geometric information source is configured to provide current geometric information of the at least one hairpin conductor element, and the processing device comprises:
a state generator configured to receive a set of information, and further configured to generate state information on the basis of the received set of information; and
an intelligent agent configured to process the state information, and to autonomously generate corrective actions for the shaping parameters using artificial intelligence (AI) algorithms;
so that the processing device adjusts the shaping parameters on the basis of the corrective actions generated by the intelligent agent.

The present invention relates to a system and a method for controlling the operations (bending, calendering, advancement and cutting) performed on an electric wire by a shaping machine for making conductor elements of the hairpin type, more briefly hairpin conductor elements, and even more briefly simply hairpins, of an inductive winding of a stator.

The system and the method according to the present invention are particularly, although not exclusively, useful and practical in the area of controlling shaping operations for the production of the hairpin conductor elements that constitute the inductive windings of stators of electric machines, for example electric motors or electricity generators.

It is known that electric motors, dynamos, alternators and transformers comprise a core of ferromagnetic material on which windings are arranged which are made of electric wires arranged according to a specific geometry. The circulation of an electric current in at least one of the windings determines, by electromagnetic induction, the circulation of an induced current in at least one other winding. Furthermore, between the ferromagnetic core and the respective windings, forces act on each other and are capable, for example, of turning a rotor with respect to a stator in an electric motor.

As said, the inductive windings described above are made using wires of electrically conducting material, generally copper. For specific applications, inductive windings are made using wire-like elements of electrically conducting material, more briefly hairpin conductor elements, which are first inserted into specific slots which are provided in the stator, i.e. the ferromagnetic core, of the electric machine under construction, and then mutually stably coupled at at least one end, typically by means of welding operations.

Typically, the inductive winding of a stator comprises hairpin conductor elements of various different shapes. Basically, a great many shapes can be made and they depend only on the capacities of the shaping machine.

Typical, but non-limiting, examples of these hairpin conductor elements are those shaped like a fork. This fork has a pair of straight shanks which are mutually connected at one end by a bridge-like crosspiece. Typically the fork is shaped approximately like an upturned U with the bridge shaped like a cusp. Each shank of the fork, and therefore of the hairpin conductor element, has a free end for insertion into a respective slot of the stator of the electric machine. In particular, a first end of each hairpin conductor element is inserted into a respective first slot, while a second end of the same hairpin conductor element is inserted into a respective second slot, according to the desired logic for the inductive winding of the electric machine.

In general, the production of a hairpin conductor element can be a sequence of N shaping operations (bending, calendering, advancement and cutting). These hairpin conductor elements are produced by shaping machines adapted to execute this sequence of shaping operations on a wire made of electrically conductive material, generally copper. The operations performed by these shaping machines are governed by shaping instructions which comprise shaping parameters, adjustable and modifiable, that make it possible to obtain hairpin conductor elements having the necessary structural characteristics (for example shape, dimension, etc.) for the use for which they are intended.

This processing of the electric wire according to the shaping instructions requires very precise operations, because the hairpin conductor elements need to be shaped to comply with size tolerances that are very low, i.e. strict. The purpose of the strict size tolerances required for shaping hairpins is to facilitate the insertion of these hairpins into the slots provided in the stator of the electric machine under construction, in particular when several hairpins inserted in a small space are simultaneously present. In fact, the aim is to provide an inductive winding that meets the required specifications.

In general, in mechanical technology, the term “tolerance” indicates a permitted deviation, in the industrial manufacture of a part, in this case a hairpin conductor element, between the ideal reference measurements, defined by the design drawings, and the effective measurements of the part produced; more precisely, the difference, or the range, between the maximum and minimum allowable measurement.

However, during the shaping of hairpin conductor elements, interference conditions, outside the shaping machine, and/or working conditions, inside the shaping machine, may arise that generate drifts that lead to the production of hairpin conductor elements that fall increasingly outside this tolerance interval and which therefore must be discarded or at least reworked. For example, interference conditions, outside the shaping machine, can comprise variations in the mechanical properties (stretch modulus, yield stress, etc.) of the electric wire, or rather of the corresponding material used, the elastic return effect or “springback”, and variations in the ambient temperature. For example, the working conditions, inside the shaping machine, can comprise play and variations due to wear, and size variations of the shaping tools (for example owing to wear or to a change of tool).

Currently, human operators are employed to judge, periodically and on a spot-check basis, the quality of the shaping operations, and as a consequence the quality of the hairpin conductor elements of an inductive winding of a stator, using adapted devices for magnification, for example a digital microscope, and/or measurement instruments for mechanical testing, for example control templates.

To simplify, a hairpin conductor element can be considered good quality if the measurements that characterize it fall within the tolerance interval described above with respect to corresponding reference measurements of a reference (or master) hairpin conductor element, which obviously depend on the specific type of hairpin conductor elements under production.

Therefore, the objective of the quality checks performed by human operators is to verify if the measurements that characterize the hairpin conductor elements fall within the tolerance interval for the corresponding reference measurements, and that therefore those hairpin conductor elements have the necessary structural characteristics for the use for which they are intended.

Note that the choice of measurements to obtain from a hairpin conductor element is very critical. In fact, these measurements must characterize the hairpin conductor element uniquely and they must stand out from the inevitable measurement noise.

Furthermore, currently, many conventional shaping machines have a set of automatic controls that detect any problems in the shaping operations and/or any defects in the hairpin conductor elements. In this case, i.e. in the event of problems and/or defects, the shaping machine emits an alarm signal (sound and/or visual), alerting the respective human operator who performs the above-mentioned quality checks on the hairpin conductor elements.

If these quality checks, performed periodically and on a sample basis, or performed as a result of an alarm signal emitted by the shaping machine, give a negative result, the human operators will act on the shaping parameters of the shaping instructions so as to recalibrate the shaping machine, adapt the operations performed by the shaping machine to the interference conditions outside the shaping machine and to the working conditions inside the shaping machine, and so return to obtaining hairpin conductor elements that conform to the specifications, i.e. which have the necessary structural characteristics for the use for which they are intended.

However, this conventional methodology is not devoid of drawbacks, among which is the fact that the quality checks and any correction of the shaping parameters of the shaping instructions depend closely on the experience and/or on the skills of the human operators who carry them out. In practice, the same human operator will act in a subjective manner and, therefore, can make different decisions in different contexts, on different days, etc.

Another drawback of this conventional methodology consists in that it entails very long reaction times, which lead to the production of great quantities of hairpin conductor elements that must be rejected even if the quality checks give a negative result.

In particular, these reaction times depend both on the time that elapses between the first hairpin produced with measurements outside of the tolerance interval and the negative result of the quality checks, and also on the time that elapses between the negative result of the quality checks and the correction of the shaping parameters of the shaping instructions.

With regard to this second point, note that there is a complex dependency between the measurements of the hairpin conductor elements, the focus of quality checks, and the shaping parameters of the shaping instructions, to be set in the shaping machine. Therefore, changes need to be made to many shaping parameters of the shaping instructions simultaneously in order to correct even a single measurement of the hairpin conductor elements. Basically, this correction process is very complex and cannot be performed by just anyone, and even a human operator with experience and skill needs a great deal of time to conclude it successfully.

A further drawback of this conventional methodology basically consists in that it leads to an iterative correction of the shaping parameters of the shaping instructions, in particular following a “trial and error” approach, which is very wasteful, in particular because of the long times required and the great difficulty of execution.

Finally, currently automatic systems are also known for controlling a shaping machine, i.e. for controlling the operations performed by a shaping machine for making hairpin conductor elements of an inductive winding of a stator.

These known automatic systems are configured to monitor the hairpin conductor elements of an inductive winding of a stator made by a shaping machine, and modify the shaping parameters of the shaping instructions when necessary, substantially without human intervention, so as to recalibrate the shaping machine, adapt the operations performed by the shaping machine to the interference conditions outside the shaping machine and to the working conditions inside the shaping machine, in order to obtain hairpin conductor elements that conform to the specifications, i.e. which have the necessary structural characteristics for the use for which they are intended.

However, these known automatic systems are also not devoid of drawbacks, among which is the fact that their operation is based on measurements of hairpin conductor elements that are associated or associable with individual shaping steps, i.e. with individual shaping operations, one step or one operation at a time, these measurements often being unreliable, difficult to define, and often too noisy.

As mentioned, the production of a hairpin conductor element can be a sequence of N shaping operations (bending, calendering, advancement and cutting).

In an ideal situation, it may seem convenient to isolate the influence of the nth shaping step, by way of respective measurements of hairpin conductor elements, so as to correct the shaping parameters of the shaping instructions relating to this step independently of the corrections required of the previous and subsequent shaping steps. For example, if it were possible to identify an angle alpha-n caused by the nth shaping step with precision, and if the angle desired_alpha_n of the reference hairpin conductor element were known, it could be possible to only correct the few shaping parameters of the shaping instructions for only the nth shaping step, using the single measurement feedback of the angle alpha_n.

However, in a real-world situation, the measurements of the hairpin conductor elements that can actually be obtained with precision and without interference from the noise of acquisition of the current geometric information depend on, and therefore are influenced by, many or even all of the shaping steps. Therefore, control becomes a very complex matter. For example, a reliable measurement is the distance between the ends of the two shanks that make up the hairpin conductor element, or briefly the distance AB, and this measurement depends on, and therefore is influenced by, all the shaping steps.

Another drawback of these known automatic systems consists in that, in following the simplified approach to control described above, which consists in proceeding with the correction of one shaping step at a time, the errors made at each shaping step are inevitably summed together, with the risk of compromising the measurements that are actually important for the hairpin conductor element, for example the AB measurement described above.

A further drawback of these known automatic systems consists in that they allow no consideration for variations in working conditions inside the shaping machine.

The aim of the present invention is to overcome the limitations of the known art described above, by devising a system and a method for controlling a shaping machine for making hairpin conductor elements of an inductive winding of a stator that makes it possible to obtain better effects than those that can be obtained with conventional solutions and/or similar effects at lower cost and with higher performance levels.

Within this aim, an aim of the present invention is to conceive a system and a method for controlling a shaping machine for making hairpin conductor elements of an inductive winding of a stator, which make it possible to compensate for variations of the shaping process, i.e. variations in the operation of the shaping machine, over time (the shaping process and/or the operation of the shaping machine are not constant over time), these variations being for example due to interference conditions and/or working conditions.

Another object of the present invention is to devise a system and a method for controlling a shaping machine for making hairpin conductor elements of an inductive winding of a stator, which make it possible to adapt the operation of the shaping machine, i.e. the operations in the shaping process executed by the latter, to the interference conditions outside the shaping machine, such as for example the variations in the mechanical properties (stretch modulus, yield stress, etc.) of the electric wire, or rather of the relevant material used, the springback, and the variations in the ambient temperature.

Another object of the present invention is to devise a system and a method for controlling a shaping machine for making hairpin conductor elements of an inductive winding of a stator, which make it possible to adapt the operation of the shaping machine, i.e. the operations in the shaping process executed by the latter, to the working conditions inside the shaping machine, such as for example play and variations due to wear.

Another object of the present invention is to conceive a system and a method for controlling a shaping machine for making hairpin conductor elements of an inductive winding of a stator that make it possible to render the forming process, in particular the operations performed by the shaping machine, independent of the capabilities and/or conditions of human operators, so passing from a subjective checking to an objective checking, which leads to predictable and repeatable results.

Another object of the present invention is to devise a system and a method for controlling a shaping machine for making hairpin conductor elements of an inductive winding of a stator that make it possible to eliminate, or at least minimize, the reaction times after the first hairpin produced with measurements outside the tolerance interval.

A further object of the present invention is to devise a system and a method for controlling a shaping machine for making hairpin conductor elements of an inductive winding of a stator that make it possible to correct at least one measurement of the hairpin conductor elements, by simultaneously modifying a plurality of shaping parameters of the shaping instructions, to be set in the shaping machine, using artificial intelligence algorithms.

Another object of the present invention is to devise a system and a method for controlling a shaping machine for making hairpin conductor elements of an inductive winding of a stator that make it possible to maintain the shaping machine comfortably within the corresponding operative extremes of shaping that could render its operation unstable and not very robust.

Another object of the present invention is to devise a system and a method for controlling a shaping machine for making hairpin conductor elements of an inductive winding of a stator that make it possible to give greater stability to the forming process, in particular to the operations performed by the shaping machine.

Another object of the present invention is to provide a system and a method for controlling a shaping machine for making hairpin conductor elements of an inductive winding of a stator that are highly reliable, easily and practically implemented, and economically competitive when compared to the known art.

This aim and these and other objects which will become better apparent hereinafter are achieved by a system for controlling a shaping machine for making hairpin conductor elements of an inductive winding of a stator, said system comprising a geometric information source of at least one hairpin conductor element obtained with said shaping machine and a processing device operatively connected to said geometric information source and connectable to said shaping machine;
wherein said geometric information source is configured to provide current geometric information of said at least one hairpin conductor element, and said processing device comprises:
a state or status generator configured to receive a set of information comprising at least said current geometric information of said hairpin conductor element provided by said geometric information source, reference geometric information of a reference hairpin conductor element, and shaping parameters used in said shaping machine, and further configured to generate state or status information on the basis of said received set of information; and
an intelligent agent configured to process said state information, and to autonomously generate corrective actions for said shaping parameters using artificial intelligence algorithms;
so that said processing device adjusts said shaping parameters on the basis of said corrective actions generated by said intelligent agent.

The aim and objects are also achieved by a method for controlling a shaping machine for making hairpin conductor elements of an inductive winding of a stator, by means of a geometric information source of at least one hairpin conductor element and a processing device operatively connected to said geometric information source and connectable to said shaping machine, said method comprising the steps of:
providing current geometric information of said at least one hairpin conductor element obtained with said shaping machine, by means of said geometric information source;
receiving a set of information comprising at least said current geometric information of said hairpin conductor element provided by said geometric information source, reference geometric information of a reference hairpin conductor element, and shaping parameters used by said shaping machine, and further generating state or status information on the basis of said received set of information, by means of a state or status generator of said processing device; and
processing said state information, and autonomously generating corrective actions for said shaping parameters, using artificial intelligence algorithms, by means of an intelligent agent of said processing device;
so that said processing device adjusts said shaping parameters on the basis of said corrective actions generated by said intelligent agent.

The present invention also relates to a shaping machine for making hairpin conductor elements of an inductive winding of a stator according to claim 15.

The present invention also relates to a system and a method for training the system for controlling a shaping machine for making hairpin conductor elements of an inductive winding of a stator according to claims 28 and 29, respectively.

Further characteristics and advantages of the present invention will become more apparent from the description of a preferred, but not exclusive, embodiment of the system and of the method for controlling a shaping machine for making hairpin conductor elements of an inductive winding of a stator according to the invention, which is illustrated by way of non-limiting example with the aid of the accompanying drawings wherein:

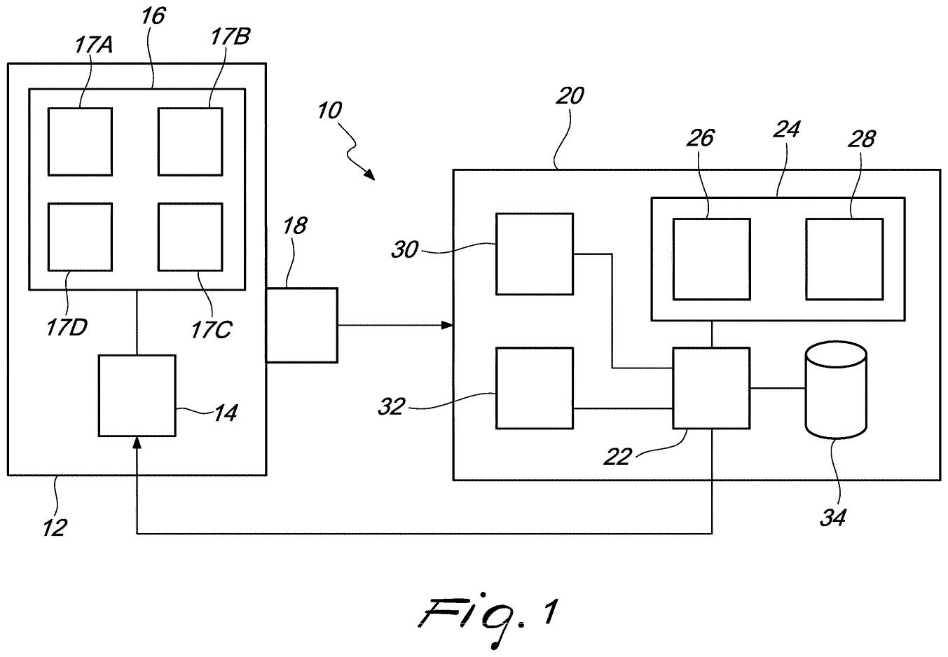

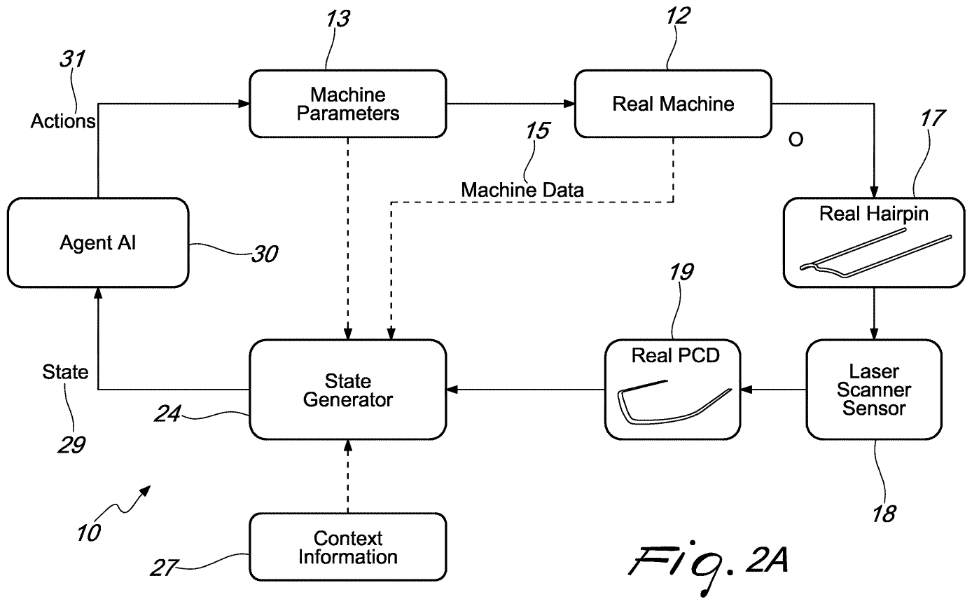

FIG. 1 is a schematic block diagram of an embodiment of the system for controlling a shaping machine for making hairpin conductor elements of an inductive winding of a stator according to the present invention;

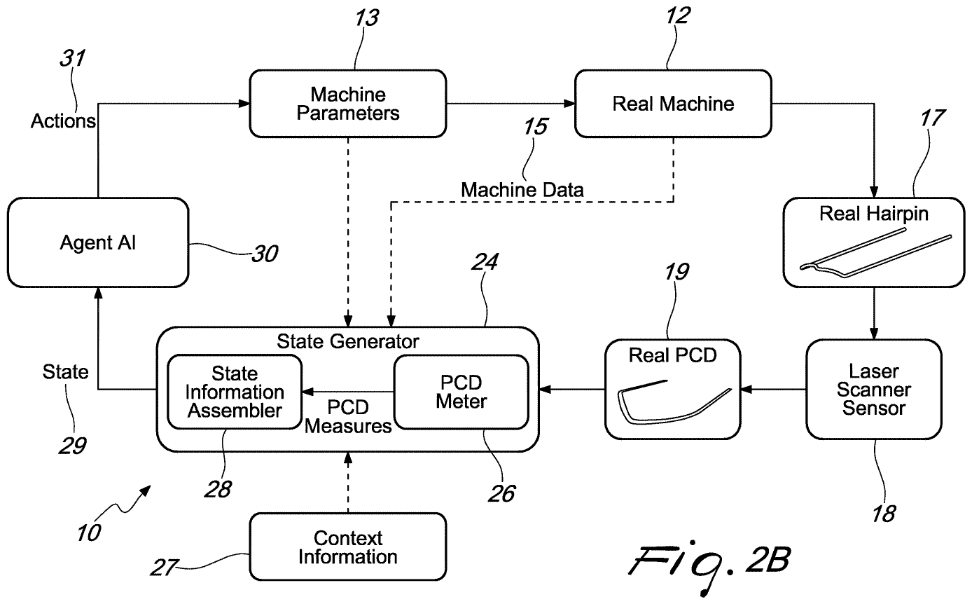

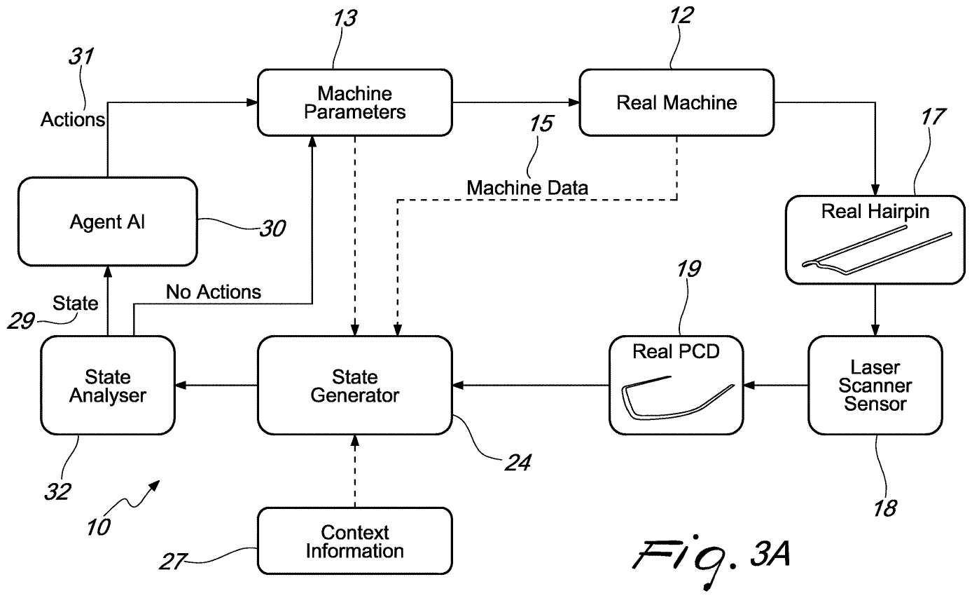

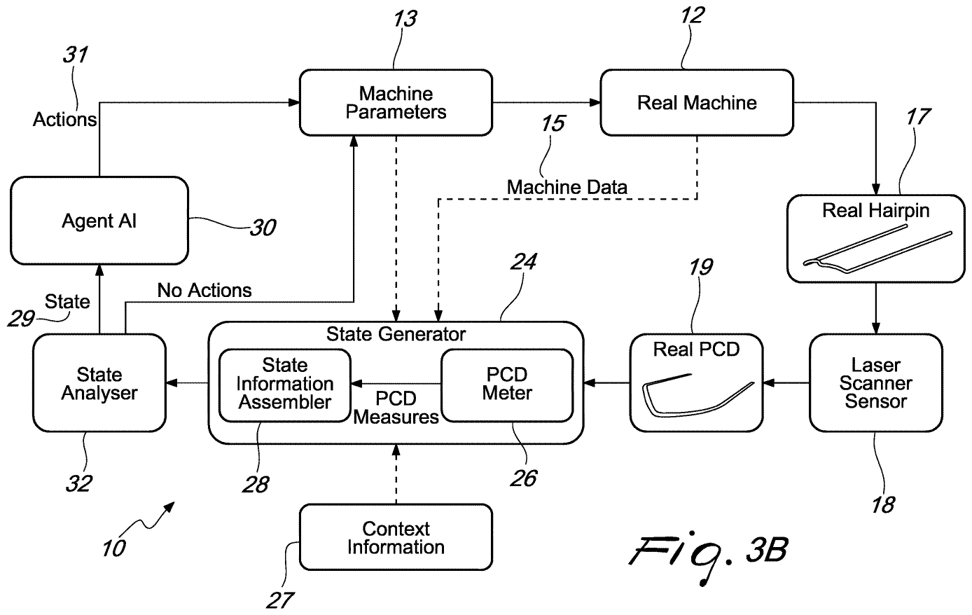

FIGS. 2A and 2B are two schematic block diagrams showing, the first in FIG. 2A in a general way and the second in FIG. 2B in detail, the elements and the data flows of a first embodiment of the system for controlling a shaping machine for making hairpin conductor elements of an inductive winding of a stator according to the present invention; FIGS. 3A and 3B are two schematic block diagrams showing, the first in FIG. 3A in a general way and the second in FIG. 3B in detail, the elements and the data flows of a second embodiment of the system for controlling a shaping machine for making hairpin conductor elements of an inductive winding of a stator according to the present invention;

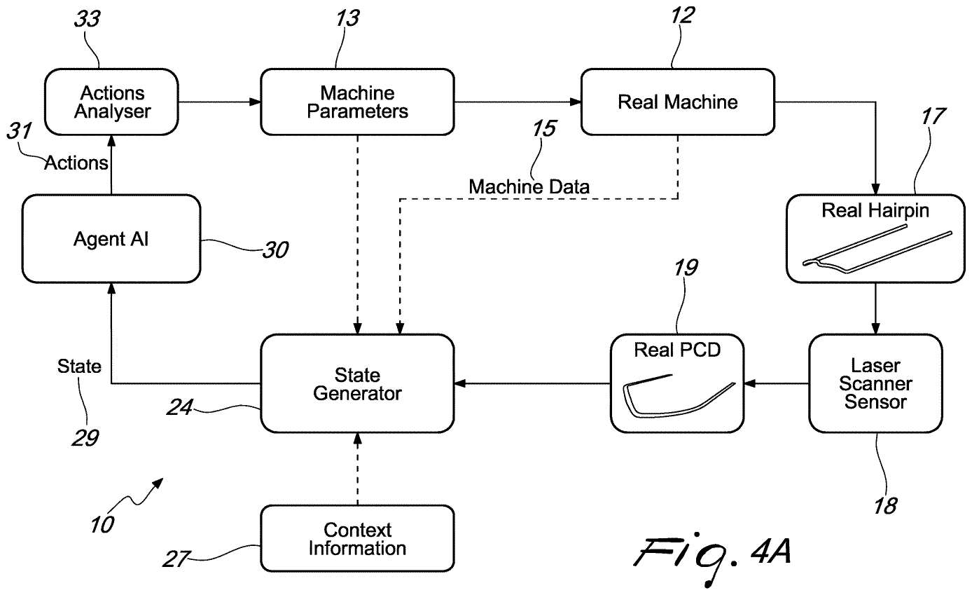

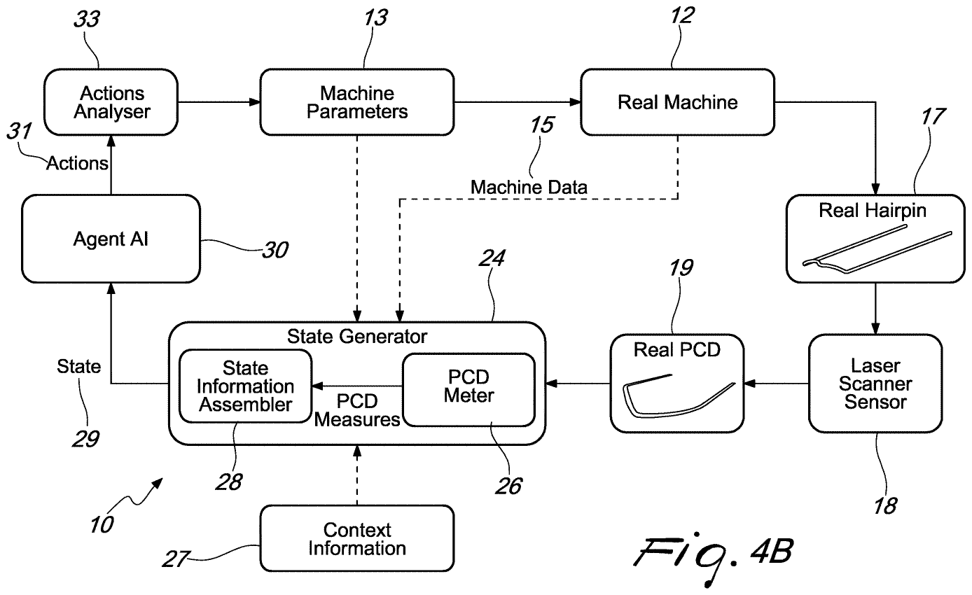

FIGS. 4A and 4B are two schematic block diagrams showing, the first in FIG. 4A in a general way and the second in FIG. 4B in detail, the elements and the data flows of a third embodiment of the system for controlling a shaping machine for making hairpin conductor elements of an inductive winding of a stator according to the present invention;

FIG. 5 is a schematic flowchart of an embodiment of the method for controlling a shaping machine for making hairpin conductor elements of an inductive winding of a stator according to the present invention;

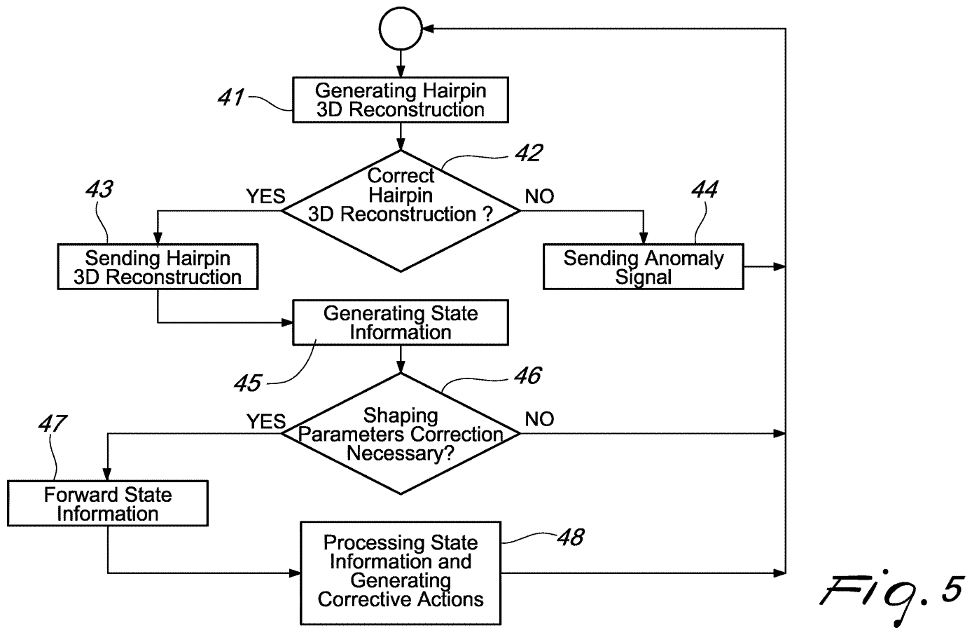

FIG. 6 is a schematic block diagram showing the data and the input information and output information of the digital twin of the shaping machine used for training an embodiment of the system for controlling a shaping machine for making hairpin conductor elements of an inductive winding of a stator according to the present invention;

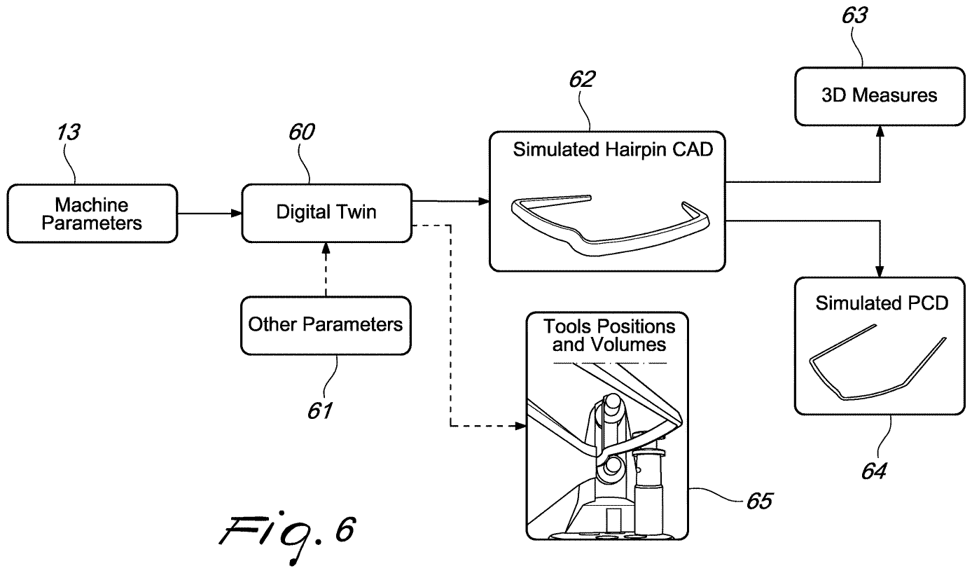

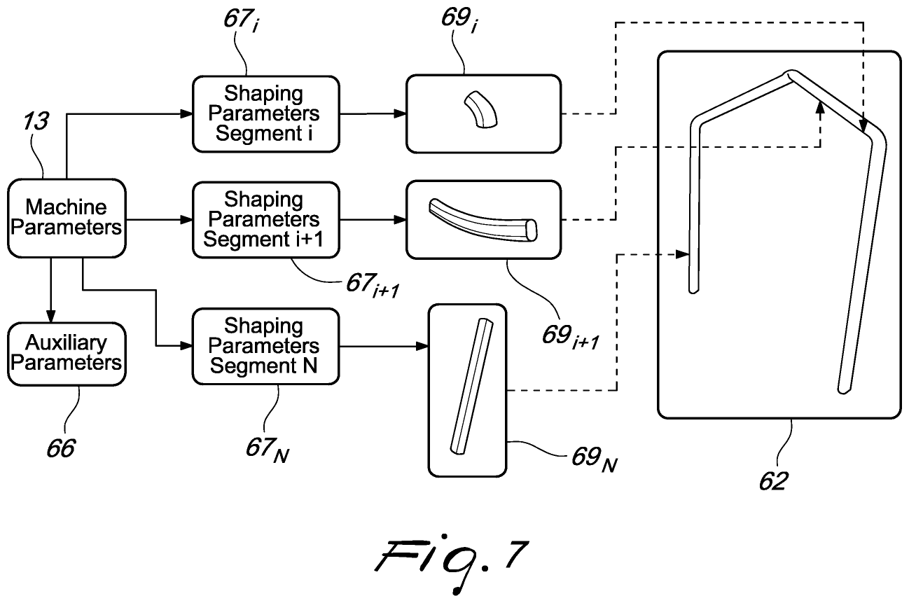

FIG. 7 is a schematic block diagram showing the logic for generating a simulated hairpin conductor element followed by the digital twin of the shaping machine used for training an embodiment of the system for controlling a shaping machine for making hairpin conductor elements of an inductive winding of a stator according to the present invention;

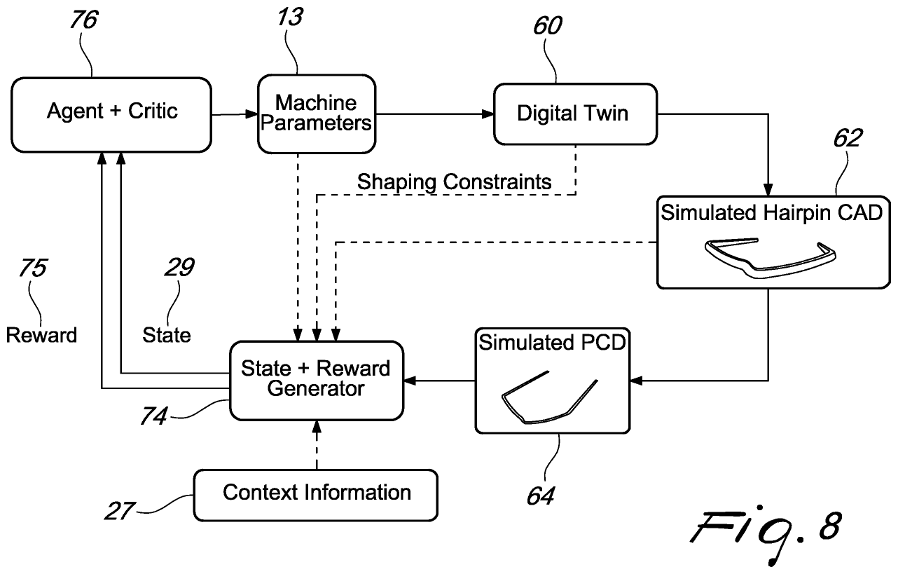

FIG. 8 is a schematic block diagram of the elements and data flows of an embodiment, in the absence of variability (or noise), of the system for training a system for controlling a shaping machine for making hairpin conductor elements of an inductive winding of a stator according to the present invention;

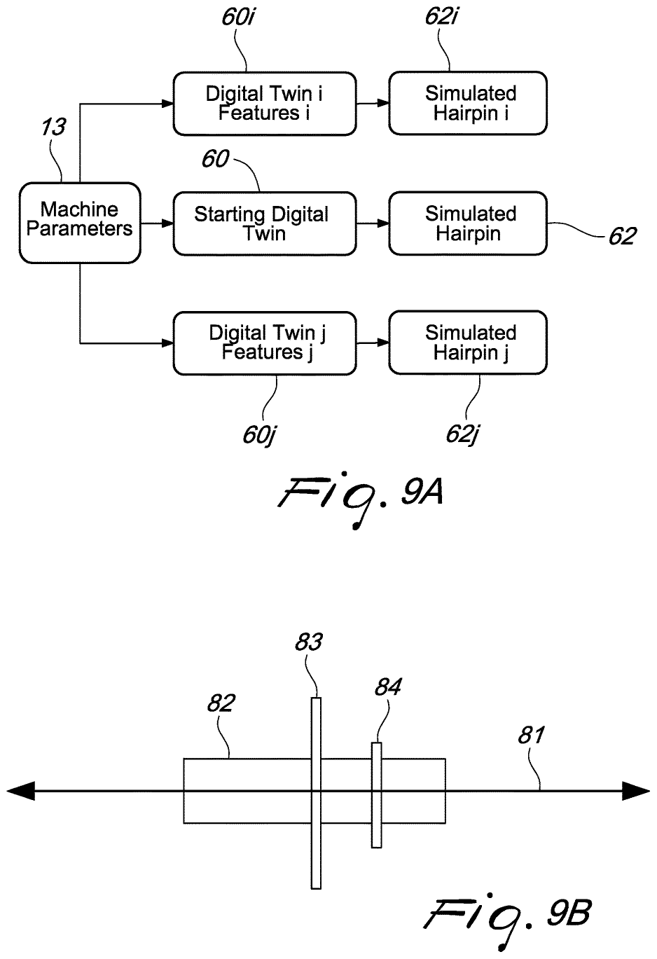

FIGS. 9A and 9B are a block diagram and a graph that schematically show the variability (or noise) in training a system for controlling a shaping machine for making hairpin conductor elements of an inductive winding of a stator according to the present invention;

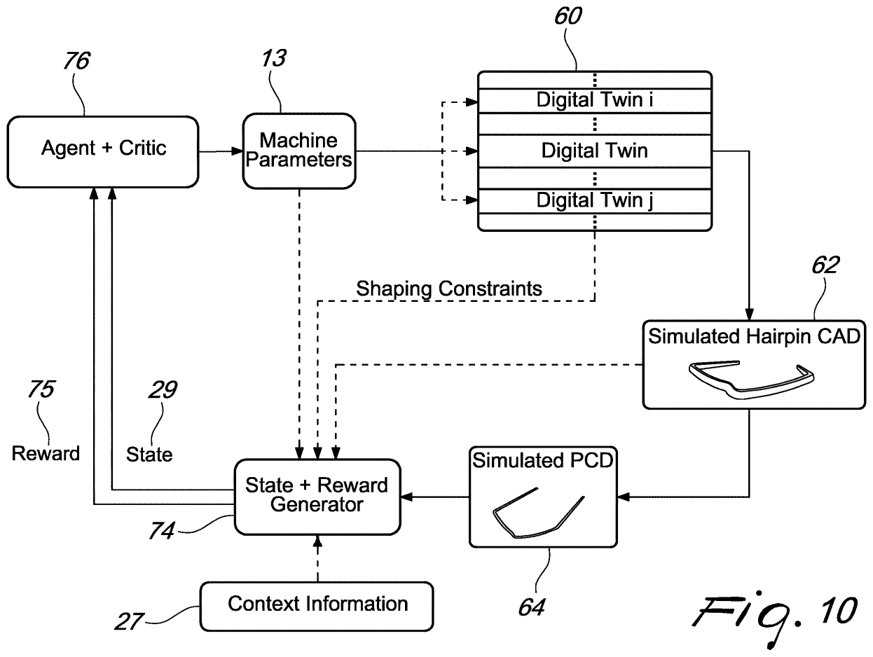

FIG. 10 is a schematic block diagram of the elements and data flows of an embodiment, in the presence of variability (or noise), of the system for training a system for controlling a shaping machine for making hairpin conductor elements of an inductive winding of a stator according to the present invention;

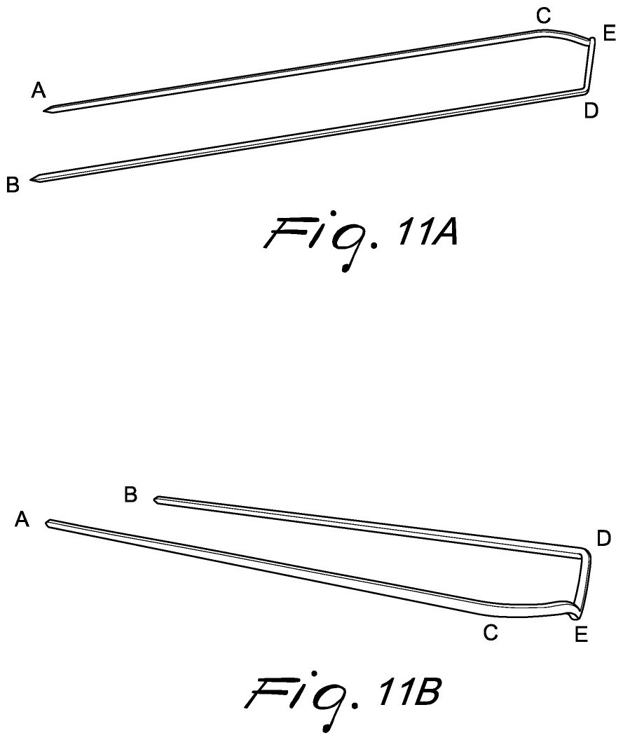

FIGS. 11A and 11B are perspective views of an example of a hairpin conductor element of an inductive winding of a stator.

With reference to FIGS. 1 to 4B, the system for controlling a shaping machine for making hairpin conductor elements of an inductive winding of a stator according to the present invention, generally designated by the reference number 10, substantially comprises a geometric information source 18, preferably three-dimensional (3D), and a processing device 20. The geometric information source 18 can be associated or associable with a shaping machine 12. The processing device 20 is operatively connected or connectable to the geometric information source 18, and vice versa. The processing device 20 is operatively connected or connectable to the shaping machine 12, and vice versa.

The shaping machine 12 is configured to make, and therefore to provide in output, a plurality of real hairpin conductor elements 17.

The shaping machine 12 comprises an electronic control unit 14, preferably of the type of a Programmable Logic Controller (PLC), and shaping means 16.

The electronic control unit 14 of the shaping machine 12 is operatively connected to the shaping means 16, and is adapted to process and to interface with the shaping means 16 and with the processing device 20.

The electronic control unit 14 of the shaping machine 12 is configured to command, control and coordinate the operation of the shaping means 16, according to the shaping instructions which, as mentioned, comprise shaping parameters 13 that make it possible to obtain hairpin conductor elements 17 that have the necessary structural characteristics for the use for which they are intended.

The shaping means 16 of the shaping machine 12 are configured to shape an electric wire into, and therefore produce, a real hairpin conductor element 17. Examples of shaping means for shaping an electric wire into a hairpin conductor element are disclosed in WO2012/156066 and WO2015/132180. The shaping means 16 of the shaping machine 12 are operatively connected to the electronic control unit 14.

Advantageously, the shaping means 16 of the shaping machine 12 comprise a plurality of electromechanical tools configured to execute the operations of bending, calendering, advancement and cutting on the electric wire, for the purpose of producing the plurality of real hairpin conductor elements 17 in output.

In an embodiment, the shaping means 16 comprise a bending unit 17A configured to execute the bending operations on the electric wire in the production of the plurality of real hairpin conductor elements 17.

In an embodiment, the shaping means 16 comprise a calendering unit 17B configured to execute the calendering operations on the electric wire in the production of the plurality of real hairpin conductor elements 17.

In an embodiment, the shaping means 16 comprise an advancement unit 17C configured to execute the advancement operations on the electric wire in the production of the plurality of real hairpin conductor elements 17.

In an embodiment, the shaping means 16 comprise a cutting unit 17D configured to execute the cutting operations on the electric wire in the production of the plurality of real hairpin conductor elements 17.

As mentioned, the operation of the shaping means 16 of the shaping machine 12 is commanded, controlled and coordinated by the electronic control unit 14, according to the shaping instructions.

The geometric information source 18 of the system 10 according to the invention is configured to provide current geometric information 19, preferably three-dimensional (3D), about at least one hairpin conductor element 17, produced by and therefore in output from the shaping machine 12. The geometric information source 18 is further configured to send the current geometric information 19 about the hairpin conductor element 17 to the processing device 20.

The geometric information source 18 can be of various types. As a consequence, the current geometric information 19 about the hairpin conductor element 17, supplied by the geometric information source 18, can be of various types. As a consequence, the accuracy of the current geometric information 19 can vary.

With reference to FIGS. 11A and 11B, the current geometric information 19 about the hairpin conductor element 17 can comprise or represent one or more measurements of said hairpin conductor element 17 selected from the group consisting of: segment AC, segment BD, segment CE, segment DE, segment CD, bending point C, bending point D, head width HeadWidth, virtual resting plane Pav, first twisting plane Pt₁, first perpendicular plane Pn₁, central bending profile S_{XYZ}, first central bending segment Sseg₁, first central bending circumference Scir₁, second central bending circumference Scir₂, second central bending segment Sseg₂, first calendering circumference C₁, first calendering plane Pc₁, first calendering radius Rc₁, second calendering circumference C₂, second calendering plane Pc₂, second calendering radius Rc₂, second twisting plane Pt₂, second perpendicular plane Pn₂, angle between twists αt, first twisting angle αt₁, second twisting angle αt₂, central bending angle βc, first bending angle β₁, second bending angle β₂, first leg trim height β₁, and second leg trim height δ₂.

For example, the current geometric information 19 about the hairpin conductor element 17 can be obtained using measurement instruments for mechanical testing, for example control templates, and then supplied by manually entering the information obtained, for example using a computer operatively connected or connectable to the processing device 20.

In an embodiment, the geometric information source 18 is a 3D vision device 18 associated or associable with a shaping machine 12. Preferably, the 3D vision device 18 is a laser scanner sensor. In this embodiment, the current geometric information 19 is a digital 3D reconstruction 19 of the hairpin conductor element 17.

The 3D vision device 18 of the system 10 according to the invention is configured to generate a digital three-dimensional (3D) reconstruction 19 of the shape or geometry (where these two terms are understood to be synonyms) of at least one hairpin conductor element 17, produced by and therefore in output from the shaping machine 12. The 3D vision device 18 is further configured to send the digital 3D reconstruction 19 of the hairpin conductor element 17 to the processing device 20.

Preferably, the current geometric information 19, for example the digital 3D reconstruction 19, of the hairpin conductor element 17, provided by the geometric information source 18, for example generated by the 3D vision device 18, is a point cloud (point cloud data, PCD), as shown in FIGS. 2A to 4B.

In an embodiment, the 3D vision device 18 is operatively connected to, or comprises, a supervisor (not shown) configured to verify the correctness, and therefore the reliability, of the digital 3D reconstruction 19 of the hairpin conductor element 17 generated by the 3D vision device 18 preliminarily, i.e. before sending it to the processing device 20. In general, a digital 3D reconstruction 19 of the hairpin conductor element 17 is correct and reliable if it is free from anomalies that are such as to render it unusable for defining the shape or geometry of the hairpin conductor element 17.

In general, three types of anomalies can currently be found in the digital 3D reconstruction 19 of the hairpin conductor element 17, i.e. they can manifest in substantially three ways.

The first type of anomaly is the lack of points in a region of the point cloud where these points should be found. Since these points are not present, it is not possible to obtain 3D geometric information about this region of the digital 3D reconstruction 19 of the hairpin conductor element 17. Consequently, it is not possible to complete the information 29 about the state of the at least one hairpin conductor element 17, generated by the state generator 24, which will be described in detail below.

The second type of anomaly is the presence of spikes, i.e. a localized region where the points detected diverge to a great extent from the adjacent points. Therefore, the 3D geometric information about that region of the digital 3D reconstruction 19 of the hairpin conductor element 17 is greatly skewed. Consequently, the information 29 about the state of the at least one hairpin conductor element 17, generated by the state generator 24, which will be described in detail below, will be incorrect.

The third type of anomaly is represented by point clouds that are “rippled”, “wrinkled” owing to anomalous oscillations that the hairpin conductor element 17 exhibits during reading with the 3D vision device 18. In this case also, the 3D geometric information about that region of the digital 3D reconstruction 19 of the hairpin conductor element 17 is greatly skewed. Consequently, the information 29 about the state of the at least one hairpin conductor element 17, generated by the state generator 24, which will be described in detail below, will be incorrect.

Advantageously, the supervisor of the 3D vision device 18 is robust to the inevitable inaccuracies in the digital 3D reconstruction 19 of the hairpin conductor element 17, generated by the 3D vision device 18. In other words, advantageously, the supervisor of the 3D vision device 18 operates on the digital 3D reconstruction 19 of the hairpin conductor element 17 by applying a predefined tolerance interval.

Advantageously, the supervisor of the 3D vision device 18 is configured to associate a numeric value with the extent or weight of any anomalies described above. If this numeric value exceeds an empirically-defined threshold, the digital 3D reconstruction 19 of the hairpin conductor element 17 is marked as incorrect, and therefore unreliable.

If the outcome of the preliminary verification executed by the supervisor of the 3D vision device 18 is positive, i.e. when the digital 3D reconstruction 19 is free from anomalies, and therefore is correct and reliable, then the 3D vision device 18 is configured to send the digital 3D reconstruction 19 of the hairpin conductor element 17 to the processing device 20.

By contrast, if the outcome of the preliminary verification executed by the supervisor of the 3D vision device 18 is negative, i.e. when the digital 3D reconstruction 19 presents anomalies, and therefore is incorrect and unreliable, the 3D vision device 18 is configured not to send the digital 3D reconstruction 19 of the hairpin conductor element 17. In this case, the supervisor of the 3D vision device 18 can be configured to send an anomaly signal for the digital 3D reconstruction 19 or the like, to the processing device 20.

The advantage of the preliminary verification executed by the supervisor of the 3D vision device 18 is that it stops at soon it starts the propagation of errors deriving from the presence of anomalies in the digital 3D reconstruction 19 of the hairpin conductor element 17. In fact, if an anomalous digital 3D reconstruction 19 of the hairpin conductor element 17 is sent to the processing device 20, it could very probably lead to incorrect evaluations and/or actions by said device, with potentially negative effects on the shaping machine 12 and, as a consequence, on the production of hairpin conductor elements 17.

The processing device 20 of the system 10 according to the invention comprises an electronic control unit 22. The electronic control unit 22 is the main functional element of the processing device 20, and for this reason it is operatively connected with the other elements comprised in the processing device 20.

The electronic control unit 22 of the processing device 20 is provided with suitable capacity for computing and for interfacing with the other elements of the processing device 20, and it is configured to command, control and coordinate the operation of the elements of the processing device 20 with which it is operatively connected.

The processing device 20 of the system 10 according to the invention further comprises a state generator 24 configured to generate state information 29, for example comprising information about the at least one hairpin conductor element 17, about the shaping machine 12, etc. In particular, the state generator 24 of the processing device 20 is configured to receive a set of information, originating from various sources, including for example the geometric information source 18 and the shaping machine 12, and then to generate the state information 29 on the basis of all this information (as such or processed).

The geometric information source 18 is configured to send the current geometric information 19 about at least one hairpin conductor element 17 to the state generator 24 of the processing device 20.

Advantageously, the state generator 24 of the processing device 20 is robust to the inevitable inaccuracies in the digital 3D reconstruction 19 of the hairpin conductor element 17, generated by the 3D vision device 18. In other words, advantageously, the state generator 24 of the processing device 20 operates on the digital 3D reconstruction 19 of the hairpin conductor element 17, by applying a predefined tolerance interval.

The set of information received by the state generator 24 of the processing device 20 can comprise one or more items of information selected from the group consisting of:
current geometric information 19 about the at least one hairpin conductor element 17, supplied by the geometric information source 18, for example, the digital 3D reconstruction 19 of the shape or geometry of the at least one hairpin conductor element 17, supplied by the 3D vision device 18;
an anomaly signal for the digital 3D reconstruction 19 originating from the supervisor (if any) of the 3D vision device 18 (if any);
shaping parameters 13 currently used by the shaping machine 12, or rather in the shaping instructions executed by the shaping machine 12;
current operative data 15 (for example speed, torque, etc.), supplied by the shaping machine 12; and
context or background information 27, for example provided by a human operator using adapted data entry means, or by the shaping machine 12, for example recorded in a memory unit 34.

As a consequence, the state information 29 can comprise one or more items of information selected from the group consisting of:
current geometric information 19 about the at least one hairpin conductor element 17, supplied by the geometric information source 18, for example, the digital 3D reconstruction 19 of the shape or geometry of the at least one hairpin conductor element 17, supplied by the 3D vision device 18, or data or measurements obtained from this digital 3D reconstruction 19;
an anomaly signal for the digital 3D reconstruction 19 originating from the supervisor (if any) of the 3D vision device 18 (if any);
shaping parameters 13 currently used by the shaping machine 12, or rather in the shaping instructions executed by the shaping machine 12;
current operative data 15 (for example speed, torque, etc.), supplied by the shaping machine 12; and
context or background information 27, for example provided by a human operator using adapted data entry means, or by the shaping machine 12, for example recorded in a memory unit 34.

The context or background information 27 for the state information 29 can comprise one or more items of information selected from the group consisting of:
reference geometric information about the reference (or master) hairpin conductor element, for example, digital 3D reconstruction of the shape or geometry of the reference (or master) hairpin conductor element, or data or measurements relating to this reference (or master) hairpin conductor element;
the type of the hairpin conductor elements 17;
the current diameter of the electric wire coil that powers the shaping machine 12; and
data about the collection basket of the hairpin conductor elements 17.

Preferably, the set of information received by the state generator 24 of the processing device 20 comprises at least:
current geometric information 19 about the at least one hairpin conductor element 17, supplied by the geometric information source 18, for example, the digital 3D reconstruction 19 of the shape or geometry of the at least one hairpin conductor element 17, supplied by the 3D vision device 18;
reference geometric information about the reference (or master) hairpin conductor element, for example, digital 3D reconstruction of the shape or geometry of the reference (or master) hairpin conductor element; and
shaping parameters 13 currently used by the shaping machine 12, or rather in the shaping instructions executed by the shaping machine 12.

Preferably, the state information 29 comprises at least:
data or measurements obtained from the digital 3D reconstruction 19 of the shape or geometry of the at least one hairpin conductor element 17;
data or measurements of the reference (or master) hairpin conductor element; and
shaping parameters 13 currently used by the shaping machine 12, or rather in the shaping instructions executed by the shaping machine 12.

Note that the reference (or master) hairpin conductor element can be real or digital, and in the second case it is therefore simulated.

Note that the choice of measurements to obtain from the current geometric information 19 of the hairpin conductor element 17 is very critical. In fact, these measurements must characterize the hairpin conductor element 17 uniquely and they must stand out from the inevitable noise of acquisition of current geometric information 19.

With reference to FIGS. 2B, 3B and 4B, in an embodiment, the state generator 24 of the processing device 20 can comprise a meter 26 configured to obtain at least one measurement of the hairpin conductor element 17 from the current geometric information 19, for example from the digital 3D reconstruction 19, of said hairpin conductor element 17. Therefore, in general, the characteristics of the hairpin conductor element 17 can be defined by at least one measurement associated with said hairpin conductor element 17.

In this embodiment, the geometric information source 18 is configured to send the current geometric information 19 of the hairpin conductor element 17 to the meter 26 of the state generator 24 of the processing device 20.

Again with reference to FIGS. 2B, 3B and 4B, in an embodiment, the state generator 24 of the processing device 20 can comprise an assembler 28 configured to generate the state information 29 by grouping together the various information available from the categories listed above in a predefined order.

In this embodiment, the state information 29 is the set of information grouped together by the assembler 28.

In an embodiment in which the state generator 24 of the processing device 20 comprises both the meter 26 and the assembler 28, the information grouped together by the latter in order to generate the state information 29 comprises the at least one measurement of the hairpin conductor element 17 obtained from the current geometric information 19, for example from the digital 3D reconstruction 19, of said hairpin conductor element 17.

The processing device 20 of the system 10 according to the invention further comprises an intelligent agent 30 configured to process the state information 29, generated and supplied by the state generator 24, and to autonomously generate corrective actions 31 that correct the shaping parameters 13 of the shaping instructions, using artificial intelligence algorithms or, more briefly, AI algorithms.

The processing device 20 is configured to send the corrective actions 31 of the shaping parameters 13 of the shaping instructions to the shaping machine 12 that executes them.

In this manner, on the basis of the outcome of processing the state information 29, executed by the intelligent agent 30, the processing device 20 recalibrates the shaping machine 12, adjusting the shaping parameters 13 used in said shaping machine 12 on the basis of the corrective actions 31 generated by the intelligent agent 30.

Basically, the intelligent agent 30 generates suitable corrective actions 31 of the shaping parameters 13 of the shaping instructions which enable the shaping machine 12 to produce the next hairpin conductor element 17 with a shape, geometry or measurements as close as possible to the shape, geometry or measurements of the reference (or master) hairpin conductor element, preferably within a predefined tolerance interval. In other words, the intelligent agent 30 generates suitable corrective actions 31 of the shaping parameters 13 of the shaping instructions which make it possible to balance the errors in the measurements of the hairpin conductor elements 17 and the constraints of the shaping machine 12.

Basically, correcting the shaping parameters 13 of the shaping instructions executed by the shaping machine 12 makes it possible to maintain the hairpin conductor elements 17 within the limits of the tolerance interval and, as a consequence, not to produce hairpin conductor elements 17 that will be discarded, or at least to limit them.

The corrective actions 31 generated by the intelligent agent 30 can comprise the corrected values of the shaping parameters 13. The corrective actions 31 generated by the intelligent agent 30 can comprise the correction variations of the values of the shaping parameters 13.

Conveniently, the intelligent agent 30 always generates corrective actions 31, even if the shape, geometry or measurements of the two hairpin conductor elements, the real one 17 produced by the shaping machine 12 and the reference (or master) one, are substantially identical. Obviously, in this case, the corrective actions 31 can produce an effect that is basically minimal and negligible, if not actually nil, on the shaping parameters 13. In other words, in this case, the shaping parameters 13 of the shaping instructions executed by the shaping machine 12 can remain substantially unchanged.

The intelligent agent 30 of the processing device 20 is configured to receive the state information 29 from the state generator 24 of said processing device 20. The state generator 24 of the processing device 20 is configured to send the state information 29 to the intelligent agent 30 of said processing device 20.

Advantageously, in a first step, the intelligent agent 30 of the processing device 20 uses the information comprised in the state information 29 to define a first transfer function between said state information 29, in particular the shaping parameters 13, and the shape or geometry (where, as mentioned, these two terms are understood to be synonyms) of said hairpin conductor element 17. Advantageously, in a second step, the intelligent agent 30 of the processing device 20 defines, by way of the first transfer function described above, a second transfer function f( ) which is used to generate the values of the shaping parameters 13 to be used to produce a hairpin conductor element 17 as close as possible to the reference (or master) hairpin conductor element.

For example, suppose x is the shape or geometry of the reference (or master) hairpin, y1 is the shape or geometry of a hairpin, hairpin_1, and z1 are the shaping parameters 13 used to make hairpin 1, with y1 being different from x. To correct the shaping parameters 13, the intelligent agent 30 uses a transfer function z2=f(x,y1,z1), where z2 after processing produces a hairpin, hairpin 2, with a shape or geometry y2 such that y2−x tends toward zero.

Basically, the intelligent agent 30 defines a first transfer function that binds z and y, on the basis of the pair z1 and y1, then uses this first transfer function to define a second transfer function f( ), with which it chooses the best z2 for the specific case it is dealing with.

The reason why it is necessary to know both y1 and z1 is that the bond between the shape or geometry of the hairpin and the shaping parameters 13 is not fixed, but can vary for many reasons, for example the material of the electric wire, the wear of the shaping machine, etc.

At least one measurement of the hairpin conductor element 17 can be obtained from the current geometric information 19 of said hairpin conductor element 17. The at least one measurement of the hairpin conductor element 17 can comprise distances, but also geometric elements such as segments, planes, points, angles, etc.

At least one measurement of the hairpin conductor element 17 can be obtained from the digital 3D reconstruction 19 of said hairpin conductor element 17, generated by the 3D vision device 18.

In an embodiment, the intelligent agent 30 of the processing device 20 can be configured to evaluate at least one measurement of the hairpin conductor element 17, produced by and therefore in output from the shaping machine 12, with respect to a corresponding measurement of the reference (or master) hairpin conductor element, supplied as context or background information 27. Preferably, the intelligent agent 30 can be configured to evaluate whether the at least one measurement of the hairpin conductor element 17 falls outside a predefined tolerance interval with respect to a corresponding measurement of the reference (or master) hairpin conductor element.

In this embodiment, the intelligent agent 30 can be configured to autonomously correct the shaping parameters 13 of the shaping instructions on the basis of the at least one measurement of the hairpin conductor element 17. In this embodiment, the intelligent agent 30 of the processing device 20 can be configured to autonomously correct the shaping parameters 13 of the shaping instructions on the basis of the difference in the at least one measurement of the hairpin conductor element 17 with respect to the corresponding measurement of the reference (or master) hairpin conductor element.

In the embodiment wherein the 3D vision device 18 comprises the supervisor, when the digital 3D reconstruction 19 is unreliable, i.e. in the presence of the anomaly signal for the digital 3D reconstruction 19 originating from said supervisor, the intelligent agent 30 of the processing device 20 can be configured not to generate any corrective action 31 to the shaping parameters 13 of the shaping instructions, so maintaining unchanged the shaping parameters 13 of the shaping instructions executed by the shaping machine 12.

Advantageously, the intelligent agent 30 is a neural network. As mentioned, there is a complex dependency between the measurements of the hairpin conductor elements, the focus of quality checks, and the shaping parameters 13 of the shaping instructions, to be set in the shaping machine 12. The use of a neural network makes it possible to intervene on many shaping parameters 13 of the shaping instructions simultaneously in order to correct even a single measurement of the hairpin conductor elements 17.

In an embodiment, the intelligent agent 30 is a fully-connected neural network (FCNN), and a feed-forward neural network (FFNN). In another embodiment, the intelligent agent 30 is a recurrent neural network (RNN). Advantageously, the intelligent agent 30 is trained using a technique, i.e. an algorithm, of automatic reinforcement learning (RL) preferably of the actor critic type, preferably with a replay buffer.

In general, the bond between the inputs and the outputs of the intelligent agent 30 is defined by the numerous weights or parameters of the neurons that make up any neural network of said intelligent agent 30. Typically, there can be hundreds of thousands, if not millions, of these weights or parameters in the neural network. Updating of these weights or parameters of the neural network is performed during the training of the intelligent agent 30, which will be described in detail below.

By way of non-limiting example, the intelligent agent 30 can be a fully-connected neural network (FCNN) and a feed-forward neural network (FFNN), constituted by an input layer that receives the state information 29, three fully connected hidden layers with a rectified linear unit (ReLU) activation function, these hidden layers being provided respectively with 256, 256 and 128 nodes, and an output layer for generating the corrective actions 31 of the shaping parameters 13 of the shaping instructions.

With reference to FIGS. 3A and 3B, in an embodiment, the processing device 20 of the system 10 according to the invention further comprises a state analyzer 32 configured to evaluate the state information 29 generated by the state generator 24 preliminarily, i.e. before sending it to the intelligent agent 30, and to then forward this evaluated state information 29 to the intelligent agent 30 when, on the basis of the outcome of the preliminary evaluation performed by said state analyzer 32, it emerges that at least one corrective action 31 is necessary.

Basically, the state analyzer 32 is configured to pre-process the state information 29, applying simpler evaluation logic than the logic applied by the intelligent agent 30 described above, and skipping, and therefore not interrogating, said intelligent agent 30 when it is not necessary to do so.

In this embodiment, the state generator 24 of the processing device 20 is configured to send the state information 29 to the state analyzer 32, instead of to the intelligent agent 30, of said processing device 20.

Advantageously, during the evaluation of the state information 29, the state analyzer 32 of the processing device 20 is further configured to compare the hairpin conductor element 17, produced by and therefore in output from the shaping machine 12, with the reference (or master) hairpin conductor element, supplied as context or background information 27, in particular between the respective digital 3D reconstructions. The purpose of this comparison is to identify any differences, for example in at least one measurement, between the two hairpin conductor elements, the real one 17 produced by the shaping machine 12 and the reference (or master) one, preferably applying a predefined tolerance interval, so as to detect the need to correct the shaping parameters 13 of the shaping instructions executed by the shaping machine 12.

As mentioned, at least one measurement of the hairpin conductor element 17 can be obtained from the current geometric information 19 of said hairpin conductor element 17. The at least one measurement of the hairpin conductor element 17 can comprise distances, but also geometric elements such as segments, planes, points, angles, etc.

As mentioned, at least one measurement of the hairpin conductor element 17 can be obtained from the digital 3D reconstruction 19 of said hairpin conductor element 17, generated by the 3D vision device 18.

In an embodiment, the state analyzer 32 of the processing device 20 can be configured to evaluate at least one measurement of the hairpin conductor element 17, produced by and therefore in output from the shaping machine 12, with respect to a corresponding measurement of the reference (or master) hairpin conductor element, supplied as context or background information 27. In particular, the state analyzer 32 can be configured to compare at least one measurement of the hairpin conductor element 17 with a corresponding measurement of the reference (or master) hairpin conductor element, supplied as context or background information 27. Preferably, the state analyzer 32 can be configured to evaluate whether the at least one measurement of the hairpin conductor element 17 falls outside a predefined tolerance interval with respect to a corresponding measurement of the reference (or master) hairpin conductor element.

In an embodiment, the state analyzer 32 of the processing device 20 can be configured to evaluate the trend of at least one measurement of a sequence or series of hairpin conductor elements 17, produced by and therefore in output from the shaping machine 12. In particular, the state analyzer 32 can be configured to compare the trend of at least one measurement of a sequence or series of hairpin conductor elements 17 with a corresponding measurement of the reference (or master) hairpin conductor element, supplied as context or background information 27. Preferably, the state analyzer 32 can be configured to evaluate whether the trend of the at least one measurement of the sequence or series of hairpin conductor elements 17 falls outside a predefined tolerance interval with respect to a corresponding reference (or master) measurement.

The objective of the above evaluation is to verify whether this trend of a measurement is divergent and (if necessary) to intervene before this measurement exceeds the tolerance interval and results in the generation of hairpin conductor elements 17 that will be rejected.

If the outcome of the preliminary evaluation performed by the state analyzer 32 is positive, i.e. when at least one corrective action 31 is required, i.e. differences are identified that fall outside the tolerance interval between the two hairpin conductor elements, and hence the decision taken by said state analyzer 32 is positive, the state analyzer 32 of the processing device 20 is configured to forward the state information 29 of the hairpin conductor element 17, or of a sequence or series of hairpin conductor elements 17, for example the last N hairpin conductor elements 17 made by the shaping machine 12, to the intelligent agent 30 of said processing device

In this embodiment, the intelligent agent 30 can be configured to autonomously correct the shaping parameters 13 of the shaping instructions on the basis of the trend of the at least one measurement in the sequence or series of hairpin conductor elements 17 with respect to the corresponding measurement of the reference (or master) hairpin conductor element. Preferably, the intelligent agent 30 can be configured to correct the shaping parameters 13 of the shaping instructions at each iteration, in order to compensate the divergent trend of a measurement, in so doing lengthening the operating time of the shaping machine 12 before it reaches its operative limit.

In an embodiment, the state analyzer 32 can be configured to alert a human operator to the presence of an anomalous trend of the measurement which, if not corrected, will over time fall outside the tolerance interval. In this manner, the human operator is alerted to a possible need for maintenance and/or intervention on the shaping machine 12.

By contrast, if the outcome of the preliminary evaluation performed by the state analyzer 32 is negative, i.e. when a corrective action 31 is not required, i.e. no differences are identified that fall outside the tolerance interval between the two hairpin conductor elements, and hence the decision taken by said state analyzer 32 is negative, the state analyzer 32 of the processing device 20 is configured not to forward the state information 29 of the hairpin conductor element 17 to the intelligent agent 30 of said processing device 20, and therefore it is configured to “skip” the intelligent agent 30.

Basically, in this case, the intelligent agent 30 of the processing device 20 does not execute any corrective action 31 of the shaping parameters 13 of the shaping instructions, in the absence of the state information 29, so maintaining unchanged the shaping parameters 13 of the shaping instructions executed by the shaping machine 12.

The preliminary evaluation performed by the state analyzer 32 of the processing device 20 has the advantage of saving at least a part of the computational resources of the processing device 20, in particular the resources used by the intelligent agent 30, if the outcome of the preliminary evaluation is negative, i.e. when no corrective action 31 is required, i.e. no differences are identified that fall outside the tolerance interval between the two hairpin conductor elements, and hence the decision taken by the state analyzer 32 is negative.

With reference to FIGS. 4A and 4B, in an embodiment, the processing device 20 of the system 10 according to the invention further comprises a corrective action analyzer 33 configured to evaluate the corrective actions 31 of the shaping parameters 13 generated by the intelligent agent 30 preliminarily, i.e. before sending them to the shaping machine 12, and then to forward these corrective actions 31 of the shaping parameters 13 to the shaping machine 12 when, on the basis of the outcome of the preliminary evaluation performed by said corrective action analyzer 33, it emerges that said corrective actions 31 comply with a predefined threshold band.

In this embodiment, the intelligent agent 30 of the processing device 20 is configured to send the corrective actions 31 of the shaping parameters 13 to the corrective action analyzer 33 of said processing device 20.

If the outcome of the preliminary evaluation performed by the corrective action analyzer 33 is positive, i.e. when the shaping parameters 13 or the correction variations of the shaping parameters 13 remain within a predefined threshold band, and therefore the decision taken by said corrective action analyzer 33 is positive, the corrective action analyzer 33 of the processing device 20 is configured to forward the corrective actions 31 of the shaping parameters 13 to the shaping machine 12.

By contrast, if the outcome of the preliminary evaluation performed by the corrective action analyzer 33 is negative, i.e. when the shaping parameters 13 or the correction variations of the shaping parameters 13 fall outside a predefined threshold band, and therefore the decision taken by said corrective action analyzer 33 is negative, the corrective action analyzer 33 of the processing device 20 is configured not to forward the corrective actions 31 of the shaping parameters 13 to the shaping machine 12, and therefore it is configured to “skip” the shaping machine 12.

Basically, in this case, the shaping machine 12 does not receive any corrective action 31 of the shaping parameters 13 of the shaping instructions, so maintaining unchanged the shaping parameters 13 of the shaping instructions executed by said shaping machine 12.

In general, the predefined threshold band described above is defined so that the shaping parameters 13 or the correction variations of the shaping parameters 13 meet a set of suitable constraints given by the limits of the shaping process and/or by the shaping machine 12, for example the space occupation of the shaping tools, the correct interaction between the shaping tools and the electric wire, etc.

If the variations of the shaping parameters 13 are too large, the preliminary evaluation performed by the corrective action analyzer 33 of the processing device 20 has the advantage of avoiding possible damage to the shaping machine 12 caused by corrective actions 31 that take the shaping parameters 13 of the shaping instructions outside the operative extremes of said shaping machine 12, these corrective actions 31 often being due to an error on the part of the intelligent agent 30.

If the variations of the shaping parameters 13 are too small, the preliminary evaluation performed by the corrective action analyzer 33 of the processing device 20 has the advantage of avoiding the application of corrective actions 31 that would be substantially ineffective on the shaping process and/or on the shaping machine 12.

In a preferred embodiment (not shown), the processing device 20 of the system 10 according to the invention further comprises both the state analyzer 32 and the corrective action analyzer 33, both described above.

Advantageously, the processing device 20 of the system 10 according to the invention further comprises a memory unit 34 configured to record the corrective actions 31 on the shaping parameters 13 of the shaping instructions executed by the shaping machine 12. In an embodiment, the memory unit 34 is moreover configured to record the current geometric information 19 of the at least one hairpin conductor element 17, supplied by the geometric information source 18. In an embodiment, the memory unit 34 is further configured to record the digital 3D reconstruction 19 of the shape or geometry of the at least one hairpin conductor element 17, supplied by the 3D vision device 18, or data or measurements obtained from this digital 3D reconstruction 19. In an embodiment, the memory unit 34 is further configured to record the reference geometric information of the reference (or master) hairpin conductor element. In an embodiment, the memory unit 34 is further configured to record the digital 3D reconstruction of the shape or geometry of the reference (or master) hairpin conductor element, or data or measurements relating to this reference (or master) hairpin conductor element. In an embodiment, the memory unit 34 is further configured to record the context or background information 27, for example provided by a human operator using adapted data entry means, or by the shaping machine 12.

With to FIG. 5, the method for controlling a shaping machine for making hairpin conductor elements of an inductive winding of a stator according to the present invention comprises the steps described below.

Initially, in step 41, current geometric information 19, preferably three-dimensional (3D) information, is supplied about at least one hairpin conductor element 17, produced by and therefore in output from a shaping machine 12, by way of a geometric information source 18. The geometric information source 18 can be associated or associable with the shaping machine 12.

As mentioned, the geometric information source 18 can be of various types. As a consequence, the current geometric information 19 about the hairpin conductor element 17, supplied by the geometric information source 18, can be of various types. As a consequence, the accuracy of the current geometric information 19 can vary.

For example, the current geometric information 19 about the hairpin conductor element 17 can be obtained and then supplied using measurement instruments for mechanical testing.

In an embodiment, the geometric information source 18 is a 3D vision device 18 associated or associable with a shaping machine 12. Preferably, the 3D vision device 18 is a laser scanner sensor. In this embodiment, the current geometric information 19 is a digital 3D reconstruction 19 of the hairpin conductor element 17. Preferably, the current geometric information 19, for example the digital 3D reconstruction 19, of the hairpin conductor element 17, provided by the geometric information source 18, for example generated by the 3D vision device 18, is a point cloud (point cloud data, PCD), as shown in FIGS. 2A to 4B.

In an embodiment, after step 41, the method proceeds directly to the subsequent step 45. In another embodiment, as shown in FIG. 5, after step 41 the method proceeds to the subsequent step 42.

In this other embodiment, in step 42, the correctness, and therefore the reliability, of the digital 3D reconstruction 19 of the hairpin conductor element 17 generated by the 3D vision device 18 is verified preliminarily, i.e. before sending anything to the processing device 20, by a supervisor (not shown) which is operatively connected to, or comprised in, said 3D vision device 18. As mentioned, in general, a digital 3D reconstruction 19 of the hairpin conductor element 17 is correct and reliable if it is free from anomalies that are such as to render it unusable for defining the shape or geometry of the hairpin conductor element 17.

As mentioned, three types of anomalies can currently be found in the digital 3D reconstruction 19 of the hairpin conductor element 17, i.e. they can manifest in substantially three ways, described above.

If the outcome of the preliminary verification executed by the supervisor of the 3D vision device 18 in step 42 is positive, i.e. when the digital 3D reconstruction 19 is free from anomalies, and therefore is correct and reliable, then in step 43 the digital 3D reconstruction 19 of the hairpin conductor element 17 is sent to a processing device 20, by means of the 3D vision device 18, and then the method proceeds to the subsequent step 45.

By contrast, if the outcome of the preliminary verification executed by the supervisor of the 3D vision device 18 in step 42 is negative, i.e. when the digital 3D reconstruction 19 presents anomalies, and therefore is incorrect and unreliable, then in step 44 the digital 3D reconstruction 19 of the hairpin conductor element 17 is not sent by means of the 3D vision device 18, and the method returns to the start, in particular to the preceding step 41, therefore “skipping” steps 43, 45, 46, 47 and 48. In this case, an anomaly signal for the digital 3D reconstruction 19 or the like can be sent to the processing device 20, by means of the supervisor of the 3D vision device 18, and then the method returns to the start, in particular to the preceding step 41, therefore “skipping” steps 43, 45, 46, 47 and 48.

In step 45 state information 29 is generated, for example comprising information about the at least one hairpin conductor element 17, on the shaping machine 12, etc., by means of a state generator 24 comprised in the processing device 20. In particular, a set of information is received, originating from various sources, including for example the geometric information source 18 and the shaping machine 12, and then the state information 29 is generated on the basis of this various information (as such or processed), by means of the state generator 24 of the processing device 20.

As mentioned, preferably the state information 29 comprises at least:
data or measurements obtained from the digital 3D reconstruction 19 of the shape or geometry of the at least one hairpin conductor element 17;
data or measurements of the reference (or master) hairpin conductor element; and
the shaping parameters 13 currently used by the shaping machine 12.

In an embodiment, still in step 45, at least one measurement of the hairpin conductor element 17 is obtained from the current geometric information 19, for example from the digital 3D reconstruction 19, about said hairpin conductor element 17, by way of a meter 26 comprised in the state generator 24 of the processing device 20. Therefore, in general, the characteristics of the hairpin conductor element 17 can be defined by at least one measurement associated with said hairpin conductor element 17.

In an embodiment, still in step 45, the state information 29 is generated by grouping together the various information available from the categories listed above in a predefined order, by means of an assembler 28 comprised in the state generator 24 of the processing device 20. In this embodiment, the state information 29 is the set of information combined by the assembler 28.

In an embodiment, after step 45 the method proceeds directly to the subsequent step 47. In another embodiment, as shown in FIG. 5, after step 45 the method proceeds to the subsequent step 46.

In this other embodiment, in step 46, the state information 29 is evaluated preliminarily, i.e. before sending it to the intelligent agent 30, and then this evaluated state information 29 is forwarded to the intelligent agent 30 when, on the basis of the outcome of the preliminary evaluation performed, it emerges that at least one corrective action 31 is necessary, by means of a state analyzer 32 comprised in the processing device 20.

Advantageously, during the evaluation of the state information 29, performed in step 46, the hairpin conductor element 17, produced by and therefore in output from the shaping machine 12, is compared with the reference (or master) hairpin conductor element, supplied as context or background information 27, in particular between the respective digital 3D reconstructions, by means of the state analyzer 32 of the processing device 20. As mentioned, the purpose of this comparison is to identify any differences, for example in at least one measurement, between the two hairpin conductor elements, the real one 17 produced by the shaping machine 12 and the reference (or master) one, preferably applying a predefined tolerance interval, so as to detect the need to correct the shaping parameters 13 of the shaping instructions executed by the shaping machine 12.

If the outcome of the preliminary evaluation performed by the state analyzer 32 in step 46 is positive, i.e. when at least one corrective action 31 is required, i.e. differences are identified that fall outside the tolerance interval between the two hairpin conductor elements, and hence the decision taken by said state analyzer 32 is positive, then in step 47 the state information 29 of the hairpin conductor element 17, or of a sequence or series of hairpin conductor elements 17, for example the last N hairpin conductor elements 17 made by the shaping machine 12, is forwarded to the intelligent agent 30 of the processing device 20, by means of the state analyzer 32 of said processing device 20, and then the method proceeds to the subsequent step 48.

By contrast, if the outcome of the preliminary evaluation performed by the state analyzer 32 in step 46 is negative, i.e. when a corrective action 31 is not required, i.e. no differences are identified that fall outside the tolerance interval between the two hairpin conductor elements, and hence the decision taken by said state analyzer 32 is negative, then the state information 29 of the hairpin conductor element 17 is not forwarded to the intelligent agent 30 of the processing device 20, by means of the state analyzer 32 of said processing device 20, and then the method returns to the start, in particular to the preceding step 41, therefore “skipping” steps 47 and 48.

Basically, in this case, step 48 is not executed, and therefore the intelligent agent 30 of the processing device 20 does not execute any corrective action 31 of the shaping parameters 13 of the shaping instructions, in the absence of the state information 29, so maintaining unchanged the shaping parameters 13 of the shaping instructions executed by the shaping machine 12.

Finally, in step 48 the state information 29 is processed, in particular evaluated, and then the method autonomously generates corrective actions 31 that correct the shaping parameters 13 of the shaping instructions, by means of an intelligent agent 30 comprised in the processing device 20.

In this manner, on the basis of the outcome of processing the state information 29, executed by the intelligent agent 30, the processing device 20 recalibrates the shaping machine 12, adjusting the shaping parameters 13 used in said shaping machine 12 on the basis of the corrective actions 31 generated by the intelligent agent 30.

As mentioned, the intelligent agent 30 generates suitable corrective actions 31 of the shaping parameters 13 of the shaping instructions which enable the shaping machine 12 to produce the next hairpin conductor element 17 with a shape, geometry or measurements as close as possible to the shape, geometry or measurements of the reference (or master) hairpin conductor element, preferably within a predefined tolerance interval. In other words, the intelligent agent 30 generates suitable corrective actions 31 of the shaping parameters 13 of the shaping instructions which make it possible to balance the errors in the measurements of the hairpin conductor elements 17 and the constraints of the shaping machine 12.

As mentioned, correcting the shaping parameters 13 of the shaping instructions executed by the shaping machine 12 makes it possible to maintain the hairpin conductor elements 17 within the limits of the tolerance interval and, as a consequence, not to produce hairpin conductor elements 17 that will be discarded, or at least to limit them.

Conveniently, the intelligent agent 30 always generates corrective actions 31, even if the shape, geometry or measurements of the two hairpin conductor elements, the real one 17 produced by the shaping machine 12 and the reference (or master) one, are substantially identical. Obviously, in this case, the corrective actions 31 can produce an effect that is basically minimal and negligible, if not actually nil, on the shaping parameters 13. In other words, in this case, the shaping parameters 13 of the shaping instructions executed by the shaping machine 12 can remain substantially unchanged.

Note that, in the embodiment comprising step 46, any lack of differences outside the tolerance interval between the two hairpin conductor elements, the real one 17 produced by the shaping machine 12 and the reference (or master) one, is found in said step 46 and that, as mentioned, in the event such a lack is found, the method returns to the start, in particular to the preceding step 41, therefore “skipping” steps 47 and 48.

In the embodiment comprising steps 42 and 44, i.e. when the digital 3D reconstruction 19 is unreliable, i.e. in the presence of the anomaly signal for the digital 3D reconstruction 19 originating from said supervisor, the intelligent agent 30 of the processing device 20 does not generate any corrective action 31 to the shaping parameters 13 of the shaping instructions, so maintaining unchanged the shaping parameters 13 of the shaping instructions executed by the shaping machine 12.

In an embodiment, the corrective actions 31 of the shaping parameters 13, defined by the intelligent agent 30 in step 48, are evaluated preliminarily, i.e. before sending them to the shaping machine 12, and then these corrective actions 31 of the shaping parameters 13 are forwarded to the shaping machine 12 when, on the basis of the outcome of the preliminary evaluation performed, it emerges that said corrective actions 31 comply with a predefined threshold band, by means of a corrective action analyzer 33 comprised in the processing device 20.

If the outcome of the preliminary evaluation performed by the corrective action analyzer 33 in the step described above is positive, i.e. when the shaping parameters 13 or the correction variations of the shaping parameters 13 remain within a predefined threshold band, and therefore the decision taken by said corrective action analyzer 33 is positive, the corrective actions 31 of the shaping parameters 13 are forwarded to the shaping machine 12, by means of the corrective action analyzer 33 of the processing device 20, and then the method returns to the start, in particular to the preceding step 41.

By contrast, if the outcome of the preliminary evaluation performed by the corrective action analyzer 33 in the step described above is negative, i.e. when the shaping parameters 13 or the correction variations of the shaping parameters 13 fall outside a predefined threshold band, and therefore the decision taken by said corrective action analyzer 33 is negative, the corrective actions 31 of the shaping parameters 13 are not forwarded to the shaping machine 12, by means of the corrective action analyzer 33 of the processing device 20, and then the method returns to the start, in particular to the preceding step 41.

As mentioned, in this case, the shaping machine 12 does not receive any corrective action 31 of the shaping parameters 13 of the shaping instructions, so maintaining unchanged the shaping parameters 13 of the shaping instructions executed by said shaping machine 12.

As mentioned, the predefined threshold band described above is defined so that the shaping parameters 13 or the correction variations of the shaping parameters 13 meet a set of suitable constraints given by the limits of the shaping process and/or by the shaping machine 12, for example the space occupation of the shaping tools, the correct interaction between the shaping tools and the electric wire, etc.

With reference to FIGS. 6 to 10, advantageously, the training of the system 10 for controlling a shaping machine for making hairpin conductor elements of an inductive winding of a stator according to the present invention, in particular the training of the intelligent agent 30 of the processing device 20, is performed by a training agent 76, which will be described in detail below, associated with at least one digital twin 60 of a shaping machine 12, where the digital twin 60 is configured to generate at least one plurality of simulated hairpin conductor elements 62 that can be used by the training agent 76 as data for training the intelligent agent 30.

Basically, in the training of the intelligent agent 30 of the processing device 20, the real shaping machine 12 described above is substituted by the digital twin 60 of a shaping machine.

Advantageously, the training data comprise a plurality of simulated shaping parameters used by the digital shaping machine implemented in the digital twin 60, these simulated shaping parameters being different from each other and emulating the real shaping parameters adoptable by the real shaping machine 12, as will be described in detail below with reference to FIG. 9B.

Advantageously, the training of the intelligent agent 30 of the processing device 20 is performed by the training agent 76 by means of the training data produced by a plurality of digital twins 60 of respective shaping machines, each one different from the others. This makes it possible to increase, directly proportionally to the number of digital twins 60 of shaping machines, the variability (or the noise) of the data for training the intelligent agent 30, supplied in input to the training agent 76.

As is known in the field of artificial intelligence, the greater the variability of the training data, the greater the quality of the training, and the better the performance (in terms of effectiveness, efficiency, speed, general applicability, robustness, etc.) of the trained system.

In the present invention, the variability (or noise) mentioned above refers to the various operative conditions under which the shaping machine can function. As mentioned, interference conditions, outside the shaping machine, can comprise variations in the mechanical properties (stretch modulus, yield stress, etc.) of the electric wire, or rather of the corresponding material used, the elastic return effect or “springback”, and variations in the ambient temperature. As mentioned, the working conditions inside the shaping machine can comprise play and variations due to wear, and size variations of the shaping tools (for example owing to wear or to a change of tool).

Using the digital twin 60 it is possible to enable the intelligent agent 30 to interface with many and varied different operative conditions, by simulating them, and to learn a policy for correcting the shaping parameters 13 of the shaping instructions, this policy being general, robust and applicable to all the operative conditions simulated and therefore explored, by means of the training process.

Note that the digital shaping machine implemented in the digital twin 60 can be (and typically is) different, in terms of characteristics, parameters, etc., from the real shaping machine 12. In other words, typically, the digital shaping machine implemented in the digital twin 60 is not an exact copy of the real shaping machine 12. However, the shaping process executed by the digital shaping machine implemented in the digital twin 60 must in any case resemble the shaping process executed by the real shaping machine 12.

Using a digital twin 60 of the shaping machine has the advantage of virtualizing the training of the system 10, in particular the training of the intelligent agent 30 of the processing device 20, so avoiding the waste of resources, for example raw materials (electric wire, electricity), time, money, etc., for shaping a sufficient number of real hairpin conductor elements 17 using a real machine 12 to generate adequate data (adequate in terms of amount and variability), the sole purpose of which is the training described above.

Note that, preferably, the training of the intelligent agent 30 requires training data for hundreds of thousands of hairpin conductor elements. In a preferred embodiment, the training of the intelligent agent 30 can be performed using training data that comprise a combination of data on real hairpin conductor elements 17 and data on simulated hairpin conductor elements 62, in particular when this training is performed by means of an automatic technique, i.e. algorithm, of automatic reinforcement learning (RL) of the actor critic type with a replay buffer. In another embodiment, the training of the intelligent agent 30 can be performed using training data that comprise only data for simulated hairpin conductor elements 62. In another embodiment, the training of the intelligent agent 30 can be performed using training data that comprise only data for real hairpin conductor elements 17.

With reference to FIG. 6, the digital twin 60 is a digital model of a digital shaping machine of hairpin conductor elements of an inductive winding of a stator. The digital twin 60 is configured by a plurality of parameters 13, 61 supplied in input to said digital twin 60.

Note that the parameters 13, 61, in particular other parameters 61, of the digital shaping machine implemented in the digital twin 60 can be (and typically are) different from those of the real shaping machine 12. In other words, typically the parameters 13, 61, in particular other parameters 61, of the digital shaping machine implemented in the digital twin 60 are not an exact copy of the parameters of the real shaping machine 12. However, since the shaping process executed by the digital shaping machine implemented in the digital twin 60 must in any case resemble the shaping process executed by the real shaping machine 12, the parameters 13, 61 of the digital shaping machine implemented in the digital twin 60 must resemble the parameters of the real shaping machine 12.

These parameters 13, 61 which configure the digital twin 60 of the shaping machine comprise the shaping parameters 13 used in the shaping instructions to be executed by said digital twin 60.

These parameters 13, 61 which configure the digital twin 60 of the shaping machine further comprise other parameters 61.

In particular, these other parameters 61 can comprise one or more parameters selected from the group constituted by: thickness of the electric wire, mechanical properties of the electric wire, geometry of the shaping machine (for example in CAD, Computer-Aided Design, format), kinematics of the shaping machine, zeroes of the shaping machine, interactions between the tools of the shaping machine, physical constraints of the shaping process, real data, and torque dispensed or current drawn by the motors of the tools of the shaping machine.

By means of the digital twin 60 it is possible to obtain, starting from the shaping parameters 13, one or more elements selected from the group constituted by: a plurality of simulated hairpin conductor elements 62, respective simulated three-dimensional (3D) measurements 63 of said simulated hairpin conductor elements 62, respective simulated three-dimensional (3D) geometric information 64 of said simulated hairpin conductor elements 62, and a plurality of data and information 65 relating to the process of shaping the plurality of simulated hairpin conductor elements 62. The bond between the shaping parameters 13 and these elements 62, 63, 64, 65 is parametrized by the other parameters 61.

As mentioned, the digital twin 60 is configured to generate a plurality of simulated hairpin conductor elements 62 that can be used by the training agent 76 as data for training the intelligent agent 30. In particular, the simulated hairpin conductor elements 62, or rather the respective shapes or geometries, can be used directly as training data and/or indirectly to obtain, generate etc. the training data.

The digital twin 60 of the shaping machine is configured to generate, in particular create virtually, and therefore supply as output, at least one plurality (or rather a sequence, since they are generated one after the other) of simulated hairpin conductor elements 62. These simulated hairpin conductor elements 62 are the ones that are obtainable on the basis of the parameters 13, 61 that configure the digital twin 60 of the shaping machine. In particular, the digital twin 60 is configured to generate, and therefore supply as output, a shape or geometry (for example in CAD, Computer-Aided Design, format), of each simulated hairpin conductor element 62 in output from said digital twin 60.

The shape or geometry (where, as mentioned, these two terms are understood to be synonyms) of the simulated hairpin conductor element 62 can be comprised in the data for training the intelligent agent 30. In other words, the training data supplied in input to the training agent 76 can comprise the shape or geometry of the simulated hairpin conductor element 62.

The digital twin 60 can be further configured to obtain, from the shape or geometry of the simulated hairpin conductor element 62 mentioned above, respective simulated three-dimensional (3D) measurements 63 of said simulated hairpin conductor element 62.

The simulated 3D measurements 63 of the shape or geometry of the plurality or sequence of simulated hairpin conductor elements 62 can be comprised in the data for training the intelligent agent 30. In other words, the training data supplied in input to the training agent 76 can comprise the simulated 3D measurements 63 of the shape or geometry of the plurality or sequence of simulated hairpin conductor elements 62.

The digital twin 60 can be further configured to generate, from the shape or geometry of the simulated hairpin conductor element 62 mentioned above, simulated geometric information 64, for example a simulated digital three-dimensional (3D) reconstruction 64, of said simulated hairpin conductor element 62.

Basically, this simulated digital 3D reconstruction 64 is a simulation of the digital 3D reconstruction 19, generated by the 3D vision device 18, of the shape or geometry of the hairpin conductor element 17, produced by and therefore in output from the shaping machine 12.

Preferably, the simulated geometric information 64, for example the simulated digital 3D reconstruction 64, of the simulated hairpin conductor element 62 is a point cloud (point cloud data, PCD).

The simulated digital 3D reconstruction 64 of the shape or geometry of the plurality or sequence of simulated hairpin conductor elements 62 can be comprised in the data for training the intelligent agent 30. In other words, the training data supplied in input to the training agent 76 can comprise the simulated digital 3D reconstruction 64 of the shape or geometry of the plurality or sequence of simulated hairpin conductor elements 62.

The digital twin 60 can be further configured to produce as output a plurality of data and information 65 about the process of shaping the plurality or sequence of simulated hairpin conductor elements 62, or of each one thereof.

In particular, this plurality of data and information 65 can comprise one or more data items and information items selected from the group constituted by: the positions and space occupation (i.e. the volumes or space taken up) of the tools during the simulated shaping, the positions of the electric wire during the simulated shaping, the interactions between the tools during the simulated shaping, the desired positions for the engagements during the simulated shaping, and the unwanted intersections between tools and electric wire during the simulated shaping.

This plurality of data items and information items 65 is the one that is obtainable with the parameters 13, 61 that configure the digital twin 60 of the shaping machine.

The plurality of data items and information items 65 relating to the process of shaping the plurality or sequence of simulated hairpin conductor elements 62, or of each one thereof, can be comprised in the data for training the intelligent agent 30. In other words, the training data supplied in input to the training agent 76 can comprise the plurality of data items and information items 65 relating to the process of shaping the plurality or sequence of simulated hairpin conductor elements 62, or of each one thereof.

With reference to FIG. 7, in an embodiment, the generation of a simulated hairpin conductor element 62 by the digital twin 60 of the shaping machine develops starting from the parameters 13, 61 that configure said digital twin 60. In other words, these parameters 13, 61 are taken as the basic source of information for the generation of a simulated hairpin conductor element 62 by the digital twin 60 of the shaping machine.

As mentioned, these parameters 13, 61 comprise the shaping parameters 13 used in the shaping instructions to be executed by said digital twin 60, and can further comprise other parameters 61.

In this embodiment, starting from the parameters 13, 61, in particular from the above-mentioned shaping parameters 13 of the shaping instructions, the digital twin 60 is configured to obtain an ordered sequence of sets of shaping parameters 67ᵢ, 67ᵢ₊₁, 67_{N}. Each set of shaping parameters 67ᵢ, 67ᵢ₊₁, 67_{N} relates to, defines and makes it possible to generate a respective segment 69ᵢ, 69ᵢ₊₁, 69_{N} of the simulated hairpin conductor element 62. Subsequently, the digital twin 60 is configured to combine the ordered sequence of segments 69ᵢ, 69ᵢ₊₁, 69_{N}, so producing the simulated hairpin conductor element 62 in its entirety.

The logic of the process described above is linked to the stepwise nature of the shaping process of any hairpin conductor element.

Each set of shaping parameters 67ᵢ, 67ᵢ₊₁, 67_{N} is a subset of the shaping parameters 13 of the shaping instructions. Each set of shaping parameters 67ᵢ, 67ᵢ₊₁, 67_{N} relates to the geometry of a respective segment 69ᵢ, 69ᵢ₊₁, 69_{N} of the simulated hairpin conductor element 62.

The combination of the various segments 69ᵢ, 69ᵢ₊₁, 69_{N} of the simulated hairpin conductor element 62 is complex. In fact, a segment 69ᵢ can be defined by a respective set of shaping parameters 67ᵢ, but then it can be modified further by the presence of another segment 69ᵢ₊₁ that comes after it. Similarly, a segment 69ᵢ₊₁ can be defined by a respective set of shaping parameters 67ᵢ₊₁, but then it can be modified further by the presence of another segment 69i that comes before it.

For example, a segment 69ᵢ could be subjected to calendering and a subsequent segment 69ᵢ₊₁ could be subjected to bending. In this case, the bending could be applied on a segment of electric wire that is already calendered, which will thus influence both what is obtained on the segment 69ᵢ₊₁ and what was previously obtained on the segment 69ᵢ.

Optionally, starting from the parameters 13, 61, in particular from the above-mentioned shaping parameters 13 of the shaping instructions, the digital twin 60 is further configured to also obtain, in addition to the ordered sequence of sets of shaping parameters 67ᵢ, 67ᵢ₊₁, 67_{N}, a set of auxiliary parameters 66 relating to the intermediate movements of the “virtual” tools of the digital twin 60 of the shaping machine.

Each set of auxiliary parameters 66 is a subset of the shaping parameters 13 of the shaping instructions. The set of auxiliary parameters 66 does not influence the geometry of the segments 69ᵢ, 69ᵢ₊₁, 69_{N} of the simulated hairpin conductor element 62, but does influence the process of shaping the hairpin conductor elements.

With reference to FIG. 8, in an embodiment without variability (or noise), the system for training the system 10 for controlling a shaping machine for making hairpin conductor elements of an inductive winding of a stator according to the invention, in particular for training the corresponding intelligent agent 30 of the processing device 20, comprises the digital twin 60 of the shaping machine described above.

Note that this embodiment without variability (or noise) of the training system according to the invention is difficult to be used in practice, because it is not very generally applicable and robust. In fact, as mentioned, it is preferable to show the training agent 76, in particular to show the automatic algorithm of the reinforcement learning (RL) type used to train the intelligent agent 30, various different operative conditions in which the shaping machine can function, so as to extrapolate from those conditions, during the training process, a policy for correcting the shaping parameters 13 of the shaping instructions that can be generalized over a plurality of operative conditions of said shaping machine.

As mentioned, the digital twin 60 is defined and configured by a plurality of parameters 13, 61 supplied in input to said digital twin 60.

As mentioned, the digital twin 60 is configured to generate, and therefore supply as output, at least one plurality or sequence of simulated hairpin conductor elements 62. These simulated hairpin conductor elements 62 are the ones that are obtainable on the basis of the parameters 13, 61 that configure the digital twin 60 of the shaping machine. In particular, the digital twin 60 is configured to generate, and therefore supply as output, geometric information (for example in CAD, Computer-Aided Design, format), of each simulated hairpin conductor element 62 in output from said digital twin 60.

As mentioned, the digital twin 60 can be further configured to obtain, from the shape or geometry of the simulated hairpin conductor element 62 mentioned above, respective simulated three-dimensional (3D) measurements 63 of said simulated hairpin conductor element 62.

As mentioned, the digital twin 60 can be further configured to generate, from the shape or geometry of the simulated hairpin conductor element 62 mentioned above, simulated geometric information 64, for example a simulated digital three-dimensional (3D) reconstruction 64, of said simulated hairpin conductor element 62.

Preferably, the simulated geometric information 64, for example the simulated digital 3D reconstruction 64, of the simulated hairpin conductor element 62 is a point cloud (point cloud data, PCD).

As mentioned, the digital twin 60 can be further configured to produce as output a plurality of data and information 65 about the process of shaping the plurality or sequence of simulated hairpin conductor elements 62, or of each one thereof. This plurality of data items and information items 65 is the one that is obtainable with the parameters 13, 61 that configure the digital twin 60 of the shaping machine.

The system for training the system 10, in particular for training the corresponding intelligent agent 30 of the processing device 20, according to the invention further comprises a state and reward generator 74 configured to generate both state information 29, for example comprising information about the simulated hairpin conductor element 62, on the digital shaping machine implemented in the digital twin 60, etc., and also reward information 75. In particular, the state and reward generator 74 of the training system is configured to receive a set of information, originating from various sources, including for example the digital twin 60, and then to generate the state information 29 on the basis of all this information (as such or processed). This state information 29 is accompanied by the reward information 75. This reward information 75 is calculated by the state and reward generator 74 on the basis of the training data described above.

The reward is a numeric value that defines the quality of the current situation, with respect to the lens assemblies, of the shaping process learned by a training agent 76, which will be described in detail below, of the training system, and as a consequence by the intelligent agent 30 of the system 10 for controlling a shaping machine.

In an embodiment, the value of the reward information 75 can be defined by one or more elements selected from the group constituted by:
the difference between the shape, geometry or measurements obtained of the simulated hairpin conductor element 62 and the shape, geometry or measurements of the reference (or master) hairpin conductor element;
one or more constraints of the shaping process; and
the shaping parameters 13 used in the shaping instructions to be executed.

The set of information received by the state and reward generator 74 of the training system can comprise one or more items of information selected from the group consisting of:
the shape or geometry of the simulated hairpin conductor element 62, supplied by the digital twin 60;
simulated 3D measurements 63 of the simulated hairpin conductor element 62, supplied by the digital twin 60;
simulated geometric information 64, for example a simulated digital 3D reconstruction 64, of the simulated hairpin conductor element 62, supplied by the digital twin 60;
the plurality of data items and information items 65 relating to the process of shaping the plurality or sequence of simulated hairpin conductor elements 62, or of each one thereof, supplied by the digital twin 60;
the shaping parameters 13 currently used in the shaping instructions to be executed by the digital twin 60;
operative constraints on shaping (for example speed, torque, etc.), supplied by the digital twin 60; and
context or background information 27, for example provided by a human operator using adapted data entry means, or by the shaping machine 12, for example recorded in a memory unit 34.

As a consequence, the state information 29 about the simulated hairpin conductor element 62 can comprise one or more items of information selected from the group consisting of:
the shape or geometry of the simulated hairpin conductor element 62, supplied by the digital twin 60;
simulated 3D measurements 63 of the simulated hairpin conductor element 62, supplied by the digital twin 60;
a simulated digital 3D reconstruction 64 of the simulated hairpin conductor element 62, supplied by the digital twin 60;
the plurality of data items and information items 65 relating to the process of shaping the plurality or sequence of simulated hairpin conductor elements 62, or of each one thereof, supplied by the digital twin 60;
the shaping parameters 13 currently used in the shaping instructions to be executed by the digital twin 60;
operative constraints on shaping (for example speed, torque, etc.), supplied by the digital twin 60; and
context or background information 27, for example provided by a human operator using adapted data entry means, or by the shaping machine 12, for example recorded in a memory unit 34.

As mentioned, the context or background information 27 for the state information 29 can comprise one or more items of information selected from the group consisting of:
reference geometric information about the reference (or master) hairpin conductor element, for example, digital 3D reconstruction of the shape or geometry of the reference (or master) hairpin conductor element, or data or measurements relating to this reference (or master) hairpin conductor element;
the type of the hairpin conductor elements 17;
the current diameter of the electric wire coil that powers the shaping machine; and
data about the collection basket of the hairpin conductor elements 17.

As mentioned, this state information 29 is accompanied by the reward information 75.

The system for training the system 10, in particular for training the corresponding intelligent agent 30 of the processing device 20, according to the invention further comprises a training agent 76, associated with said intelligent agent 30, and configured to process the state information 29 and the reward 75, generated and supplied by the state and reward generator 74, and to define and execute self-configuration or self-adjustment actions (basically, the training agent 76 executes these actions on itself, and consequently on the intelligent agent 30 that said training agent 76 is training) which will influence the shaping parameters 13 of the shaping instructions, using artificial intelligence algorithms, AI algorithms for short, so as to recalibrate the digital twin 60 on the basis of the corrective actions 31 generated by the intelligent agent 30. In short, the training agent 76 is configured to train the intelligent agent 30.

The object of the training agent 76 is to maximize the reward 75, so the self-configuration or self-adjustment actions described above are defined for the purpose of maximizing the reward 75. In other words, the training agent 76 defines and executes the self-configuration or self-adjustment actions described above so as to maximize at least one target function (or cost function) based on the reward 75, i.e. within which the reward 75 obtained in each episode has a fundamental role.

In an embodiment, the training agent 76 is a fully-connected neural network (FCNN), and a feed-forward neural network (FFNN). In another embodiment, the training agent 76 is a recurrent neural network (RNN). Advantageously, the training agent 76 implements a technique, i.e. an algorithm, of automatic reinforcement learning (RL) preferably of the actor critic type, preferably with a replay buffer. In other words, advantageously, the training agent 76 trains the intelligent agent 30 using a technique, i.e. an algorithm, of automatic reinforcement learning (RL) preferably of the actor critic type, preferably with a replay buffer.

As mentioned, the greater the variability of the training data, the greater the quality of the training, and the better the performance (in terms of effectiveness, efficiency, speed, general applicability, robustness, etc.) of the trained system.

With reference to FIG. 9A, in the training of a system for controlling a shaping machine for making hairpin conductor elements of an inductive winding of a stator according to the present invention, the variability (or the noise) of the training data can be increased by defining and configuring a plurality of digital twins 60, each one different from the others.

Advantageously, starting from the shaping parameters 13 used in the shaping instructions to be executed, and from a starting or base digital twin 60 configured to generate a respective plurality of simulated hairpin conductor elements 62, it is possible to define other digital twins 60i, 60j configured to generate respective pluralities of simulated hairpin conductor elements 62i, 62j, in particular by varying respective other parameters 61 and consequently respective shaping characteristics i, j.

Basically, out of all the possible values of the other parameters 61, a set is identified that can be called a starting set or base set and which defines the starting or base digital twin 60. Then, said other parameters 61 are varied, while still keeping them in a neighborhood of the other starting parameters 61, so as to define the other digital twins 60i, 60j.

In other words, given a starting set or base set of other parameters 61, the digital shaping machine implemented in the starting or base digital twin 60 simulates a specific shaping process. Clearly, the digital shaping machine implemented in the digital twin 60 can be used to generate, in particular create virtually, simulated hairpin conductor elements 62 with many different shapes, with the object of training the intelligent agent 30 on all these shapes, which however depend on specific conditions of the shaping process.

Advantageously, in order to increase the general applicability of the training of the intelligent agent 30, the set of other parameters 61 is varied, so generating the variability (or the noise). Thus a plurality of possible scenarios of the shaping process can be explored, with the digital twins 60i, 60j receiving as input the same machine parameters 13 and the respective other, varied parameters 61.

Keeping the other parameters 61 unchanged leads to training an intelligent agent 30 that is capable of efficiently correcting the shaping process only under specific conditions. Conveniently, by contrast, the other parameters 61 are varied during the training process, so generating the variability (or the noise), so that the training agent 76 interacts with all the possible scenarios of the shaping process and trains an intelligent agent 30 to be capable of efficiently correcting the shaping process in a great many conditions. In this manner a control system 10 is obtained that is more general and robust.

With reference to FIG. 9B, the plurality of digital twins 82, each one different from the others, on which the training is based, extends along a portion of the domain of existing shaping machines 81. Within the plurality of digital twins 82, and therefore within the domain of existing shaping machines 81, both the starting or base digital twin 83 and the real shaping machine 84 are positioned.

As mentioned, the shaping process executed by the shaping machines implemented in the digital twins 82, i.e. the simulated shaping process, must in any case resemble the shaping process executed by the real shaping machine 84.

FIG. 9B is a graphic representation of the importance of having the shaping processes executed by the shaping machines of the plurality of digital twins 82, i.e. the simulated shaping processes observed during the training process, similar, and therefore close together along the domain of existing shaping machines 81, to the shaping process executed by the real shaping machine 84. Similarly, FIG. 9B is a graphic representation of the importance of the closeness between the starting or base digital twin 83 and the real shaping machine 84. At the same time, FIG. 9B is a graphic representation of the importance of having an extent of the plurality of digital twins 82 that is sufficiently broad as to include the variations of the shaping processes, and therefore the movements along the domain of existing shaping machines 81, of the real shaping machines 84.

The capacity of the intelligent agent 30 to adapt itself, or rather to adapt the shaping parameters 13 of the shaping instructions, to the variations of the shaping processes executed by the real shaping machines is obtained by making the training agent 76, which as mentioned can train the intelligent agent 30 using an automatic reinforcement learning algorithm of the actor critic type, interact with the plurality of digital twins 82 having parameters 13, 61, in particular other parameters 61, that are variable (varied with each episode of training), thus simulating the shaping processes executed by the shaping machines of the plurality of digital twins 82.

Basically, by means of the training process, it is possible to teach the intelligent agent 30 a correction policy for the shaping parameters 13 of the shaping instructions that is extendable, and therefore adaptable, to the plurality of digital twins 82.

Note that, as the extent of the plurality of digital twins 82 increases, the general applicability and robustness also increase of the correction policy for the shaping parameters 13 of the shaping instructions learned by the intelligent agent 30 during the training process, with the risk of losing efficiency in terms of corrective performance (for example, to correct a hairpin conductor element three corrective steps are needed instead of two corrective steps).

With reference to FIG. 10, in an embodiment with variability (or noise), the system for training the system 10 for controlling a shaping machine for making hairpin conductor elements of an inductive winding of a stator according to the invention is substantially the same as what is shown in FIG. 8 and described with reference to said FIG. 8, except for the fact that it comprises a plurality of digital twins 60, each one different from the others, of the shaping machine.

In practice it has been found that the present invention fully achieves the set aim and objects. In particular, the system and the method for controlling a shaping machine for making hairpin conductor elements of an inductive winding of a stator, thus conceived, make it possible to overcome the qualitative limitations of the known art, in that they make it possible to obtain better effects than those that can be obtained with conventional solutions and/or similar effects at lower cost and with higher performance levels.

An advantage of the system and of the method for controlling a shaping machine for making hairpin conductor elements of an inductive winding of a stator according to the present invention consists in that they make it possible to compensate for variations of the shaping process, i.e. variations in the operation of the shaping machine, over time (the shaping process and/or the operation of the shaping machine are not constant over time), these variations being for example due to interference conditions and/or working conditions.

Another advantage of the system and of the method for controlling a shaping machine for making hairpin conductor elements of an inductive winding of a stator according to the present invention consists in that they make it possible to adapt the operation of the shaping machine, i.e. the operations in the shaping process executed by the latter, to the interference conditions outside the shaping machine, such as for example the variations in the mechanical properties (stretch modulus, yield stress, etc.) of the electric wire, or rather of the relevant material used, the springback, and the variations in the ambient temperature.

Another advantage of the system and of the method for controlling a shaping machine for making hairpin conductor elements of an inductive winding of a stator according to the present invention consists in that they make it possible to adapt the operation of the shaping machine, i.e. the operations in the shaping process executed by the latter, to the working conditions inside the shaping machine, such as for example play and variations due to wear.

For example, the system and the method for controlling a shaping machine for making hairpin conductor elements of an inductive winding of a stator according to the present invention are capable of handling the variations in the shaping process that may exist between different shaping machines of the same model, or the wear of the tools of a shaping machine that, over time, changes the operation of said shaping machine, or the variability of the material that makes up the electric wire with which the hairpin conductor elements are made.

Another advantage of the system and of the method for controlling a shaping machine for making hairpin conductor elements of an inductive winding of a stator according to the present invention consists in that they make it possible to make the forming process, in particular the operations performed by the forming machine, independent of the capabilities and/or conditions of human operators, so passing from a subjective checking to an objective checking, which leads to predictable and repeatable results.

Another advantage of the system and of the method for controlling a shaping machine for making hairpin conductor elements of an inductive winding of a stator according to the present invention consists in that they make it possible to eliminate, or at least minimize, the reaction times after the first hairpin produced with measurements outside the tolerance interval.

Another advantage of the system and of the method for controlling a shaping machine for making hairpin conductor elements of an inductive winding of a stator according to the present invention consists in that they make it possible to correct at least one measurement of the hairpin conductor elements, by simultaneously modifying a plurality of shaping parameters of the shaping instructions, to be set in the shaping machine, using artificial intelligence algorithms.

Another advantage of the system and of the method for controlling a shaping machine for making hairpin conductor elements of an inductive winding of a stator according to the present invention consists in that they make it possible to maintain the shaping machine comfortably within the corresponding operative extremes of shaping that could render its operation unstable and not very robust.

Another advantage of the system and of the method for controlling a shaping machine for making hairpin conductor elements of an inductive winding of a stator according to the present invention consists in that they make it possible to give greater stability to the shaping process, in particular to the operations performed by the shaping machine.

The invention, thus conceived, is susceptible of numerous modifications and variations, all of which are within the scope of the appended claims.

Except where indicated otherwise, the various embodiments described above can be combined in order to provide further and/or alternative embodiments. In addition, the present description covers combinations of variations and preferred embodiments that are not explicitly described.

Moreover, all the details may be substituted by other, technically equivalent elements.

In practice the materials employed, provided they are compatible with the specific use, and the contingent dimensions and shapes, may be any according to requirements and to the state of the art.

In conclusion, the scope of protection of the claims shall not be limited by the explanations or by the preferred embodiments illustrated in the description by way of examples, but rather the claims shall comprise all the patentable characteristics of novelty that reside in the present invention, including all the characteristics that would be considered as equivalent by the person skilled in the art.

The disclosures in Italian Patent Application No. 102023000008631 from which this application claims priority are incorporated herein by reference.

Where the technical features mentioned in any claim are followed by reference numerals and/or signs, those reference numerals and/or signs have been included for the sole purpose of increasing the intelligibility of the claims and accordingly, such reference numerals and/or signs do not have any limiting effect on the interpretation of each element identified by way of example by such reference numerals and/or signs.

1-29. (canceled)

30. A system for controlling a shaping machine for making hairpin conductor elements of an inductive winding of a stator, said system comprising a geometric information source of at least one hairpin conductor element obtained with said shaping machine and a processing device operatively connected to said geometric information source and connectable to said shaping machine;
wherein said geometric information source is configured to provide current geometric information of said at least one hairpin conductor element, and said processing device comprises:
a state generator configured to receive a set of information comprising at least said current geometric information of said hairpin conductor element provided by said geometric information source, reference geometric information of a reference hairpin conductor element, and shaping parameters used by said shaping machine, and further configured to generate state information on the basis of said received set of information; and
an intelligent agent configured to process said state information, and to autonomously generate corrective actions for said shaping parameters using artificial intelligence (AI) algorithms;
so that said processing device adjusts said shaping parameters on the basis of said corrective actions generated by said intelligent agent.

31. The system according to claim 30, wherein said geometric information source is a 3D vision device, and wherein said current geometric information is a digital 3D reconstruction of said hairpin conductor element.

32. The system according to claim 31, wherein said digital 3D reconstruction of said hairpin conductor element, generated by said 3D vision device, is a point cloud.

33. The system according to claim 31, wherein said 3D vision device is operatively connected to a supervisor configured to preliminarily verify the reliability of said digital 3D reconstruction of said hairpin conductor element, said 3D vision device being configured to send said digital 3D reconstruction to said processing device when said digital 3D reconstruction is reliable.

34. The system according to claim 33, wherein said supervisor of said 3D vision device is further configured to send an anomaly signal of said digital 3D reconstruction to said processing device when said digital 3D reconstruction is unreliable.

35. The system according to claim 33, wherein said intelligent agent of said processing device is configured to maintain said shaping parameters of said shaping machine unchanged when said digital 3D reconstruction is unreliable.

36. The system according to claim 30, wherein said state generator of said processing device comprises a meter configured to obtain at least one measurement of said hairpin conductor element from said current geometric information of said hairpin conductor element.

37. The system according to claim 30, wherein said processing device further comprises a state analyzer configured to preliminarily evaluate said state information, and to forward said evaluated state information to said intelligent agent when at least one corrective action is necessary.

38. The system according to claim 37, wherein said state analyzer of said processing device is further configured to compare said current geometric information of said hairpin conductor element with said reference geometric information of said reference hairpin conductor element, to identify any differences.

39. The system according to claim 30, wherein said processing device further comprises a corrective action analyzer configured to preliminarily evaluate said corrective actions for said shaping parameters, and to forward said corrective actions to said shaping machine when said corrective actions comply with a predefined threshold band.

40. The system according to claim 30, wherein said intelligent agent of said processing device is trained by means of a training agent associated with at least one digital twin of said shaping machine, said digital twin being a digital model of a digital shaping machine of hairpin conductor elements of an inductive winding of a stator, said digital twin being configured to generate at least a plurality of simulated hairpin conductor elements usable as training data for said training agent.

41. The system according to claim 40, wherein said training data comprise a plurality of simulated shaping parameters used by said digital shaping machine of said digital twin, said simulated shaping parameters being different from each other and emulating the real shaping parameters adoptable by said real shaping machine.

42. The system according to claim 40, wherein said digital twin is further configured to obtain simulated 3D measurements of each simulated hairpin conductor element, said training data comprising said simulated 3D measurements.

43. The system according to claim 40, wherein said digital twin is further configured to generate a simulated digital 3D reconstruction of each simulated hairpin conductor element, said training data comprising said simulated digital 3D reconstruction.

44. A shaping machine for making hairpin conductor elements of an inductive winding of a stator, wherein said shaping machine comprises shaping means configured to shape an electric wire into a hairpin conductor element, and a control system according to claim 30.

45. A method for controlling a shaping machine for making hairpin conductor elements of an inductive winding of a stator, by means of a geometric information source of at least one hairpin conductor element and a processing device operatively connected to said geometric information source and connectable to said shaping machine, said method comprising the steps of:
providing current geometric information of said at least one hairpin conductor element obtained with said shaping machine, by means of said geometric information source;
receiving a set of information comprising at least said current geometric information of said hairpin conductor element provided by said geometric information source, reference geometric information of a reference hairpin conductor element, and shaping parameters used by said shaping machine, and further generating state information on the basis of said received set of information, by means of a state generator of said processing device; and
processing said state information, and autonomously generating corrective actions for said shaping parameters, using artificial intelligence (AI) algorithms, by means of an intelligent agent of said processing device;
so that said processing device adjusts said shaping parameters on the basis of said corrective actions generated by said intelligent agent.

46. The method according to claim 45, wherein said geometric information source is a 3D vision device and wherein said current geometric information is a digital 3D reconstruction of said hairpin conductor element.

47. The method according to claim 46, wherein said digital 3D reconstruction of said hairpin conductor element, generated by said 3D vision device at said step of providing, is a point cloud.

48. The method according to claim 46, further comprising the steps of:
preliminarily verifying the reliability of said digital 3D reconstruction of said hairpin conductor element, by means of a supervisor included in said 3D vision device; and
sending said digital 3D reconstruction to said processing device when said digital 3D reconstruction is reliable, by means of said 3D vision device.

49. The method according to claim 48, further comprising the step of sending an anomaly signal of said digital 3D reconstruction to said processing device when said digital 3D reconstruction is unreliable, by means of said supervisor of said 3D vision device.

50. The method according to claim 48, further comprising the step of maintaining unchanged said shaping parameters, when said digital 3D reconstruction is unreliable.

51. The method according to claim 45, wherein said step of receiving said set of information and generating said state information comprises the step of obtaining at least one measurement of said hairpin conductor element from said current geometric information of said hairpin conductor element, by means of a meter included in said state generator of said processing device.

52. The method according to claim 45, further comprising the step of preliminarily evaluating said state information, and forwarding said evaluated state information to said intelligent agent when at least one corrective action is necessary, by means of a state analyzer of said processing device.

53. The method according to claim 52, wherein said step of preliminarily evaluating said state information and deciding whether to forward said state information to said intelligent agent comprises the step of comparing said current geometric information of said hairpin conductor element with said reference geometric information of said reference hairpin conductor element, to identify any differences, by means of said state analyzer of said processing device.

54. The method according to claim 45, further comprising the step of preliminarily evaluating said corrective actions for said shaping parameters, and forwarding said corrective actions to said shaping machine when said corrective actions comply with a predefined threshold band, by means of a corrective action analyzer of said processing device.

55. The method according to claim 45, further comprising the step of training said intelligent agent of said processing device, by means of a training agent associated with at least one digital twin of said shaping machine, said digital twin being a digital model of a digital shaping machine of hairpin conductor elements of an inductive winding of a stator, said digital twin being configured to generate at least a plurality of simulated hairpin conductor elements usable as training data for said training agent.

56. The method according to claim 55, wherein said training data comprise a plurality of simulated shaping parameters used by said digital shaping machine of said digital twin, said simulated shaping parameters being different from each other and emulating the real shaping parameters adoptable by said real shaping machine.
